(19) United States
(12) Patent Application Publication
(10) Pub. No.: US 2017/0235381 A1
(43) Pub. Date: Aug. 17, 2017

(54) Information Processing Device

(71) Applicant: Semiconductor Energy Laboratory Co., Ltd., Kanagawa-ken (JP)

(72) Inventor: Haruki Katagiri, Atsugi (JP)

(73) Assignee: Semiconductor Energy Laboratory Co., Ltd., Kanagawa-ken (JP)

(21) Appl. No.: 15/427,758

(22) Filed: Feb. 8, 2017

(30) Foreign Application Priority Data
Feb. 11, 2016 (JP) 2016-024221

(51) Int. Cl. G06F 3/0346; H01L 27/12; H01L 51/52; H01L 27/32; H01L 31/16; H05K 5/00; H01L 29/786

(52) U.S. Cl. CPC G06F 3/0346; H05K 5/0017; H01L 27/1225; H01L 27/124; H01L 29/7869; H01L 27/3276; H01L 27/3227; H01L 31/165; H01L 51/5271

(57) ABSTRACT

A novel information processing device with high convenience or high reliability is provided. Furthermore, a novel semiconductor device with high convenience or high reliability is provided. The information processing device includes a housing, an attitude sensor, a plurality of photosensors, and an arithmetic device. The attitude sensor has a function of sensing an attitude of the housing and a function of supplying attitude information based on the attitude. The housing includes a plurality of regions. The photosensors have a function of measuring illuminance in each of the plurality of regions and a function of supplying illuminance information based on the illuminance. The arithmetic device has a function of selecting one region on the basis of the attitude information and a function of operating on the basis of the illuminance information of the selected region.

### BACKGROUND OF THE INVENTION

1. Field of the Invention

One embodiment of the present invention relates to an information processing device or a semiconductor device.

Note that one embodiment of the present invention is not limited to the above technical field. The technical field of one embodiment of the present invention disclosed in this specification and the like relates to an object, a method, or a manufacturing method. Furthermore, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

2. Description of the Related Art

A liquid crystal display device in which a light-condensing means and a pixel electrode are provided on the same surface side of a substrate and a region transmitting visible light in the pixel electrode is provided to overlap with an optical axis of the light-condensing means, and a liquid crystal display device which includes an anisotropic light-condensing means having a condensing direction X and a non-condensing direction Y that is along a longitudinal direction of a region transmitting visible light in the pixel electrode are known (Patent Document 1).

### REFERENCE

### Patent Document

### [Patent Document 1] Japanese Published Patent Application No. 2011-191750

### SUMMARY OF THE INVENTION

An object of one embodiment of the present invention is to provide a novel information processing device that is highly convenient or reliable. Another object is to provide a novel information processing device or a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1) One embodiment of the present invention is an information processing device that includes a housing, an attitude sensor, a plurality of photosensors, and an arithmetic device.

The attitude sensor has a function of sensing an attitude of the housing and a function of supplying attitude information based on the sensed attitude.

The housing includes a plurality of regions.

The photosensors have a function of measuring illuminance in each of the plurality regions of the housing and a function of supplying illuminance information based on the illuminance.

The arithmetic device has a function of selecting at least one region from the plurality of regions on the basis of the attitude information and a function of operating on the basis of the illuminance information of the selected region.

Thus, the information processing device can identify the intensity of light received by the housing of the information processing device and operate under a usage environment. Furthermore, for example, the information processing device can identify a region which is hardly blocked by a hand or the like which holds the housing, and can identify the intensity of the light received by the region and operate. As a result, a novel information processing device with high convenience or high reliability can be provided.

(2) Furthermore, another embodiment of the present invention is the above-described information processing device in which the arithmetic device has a function of selecting a region positioned on the top among the plurality of regions.

Thus, the information processing device can identify the intensity of light received by the region located on the top among the plurality of regions of the housing and operate. Furthermore, the information processing device can identify the intensity of light received by the region which is hardly blocked by a hand or the like that holds the housing and is located on the top and operate among the plurality of regions included in the housing, for example. As a result, a novel information processing device with high convenience or high reliability can be provided.

(3) Another embodiment of the present invention is the above-described information processing device that includes a plurality of photosensors.

The region includes any one of the plurality of photosensors.

The photosensors supply illuminance information in the region where the photosensor are provided.

(4) Another embodiment of the present invention is the above-described information processing device that includes a sensor portion.

The sensor portion has a function of driving the photosensor of the selected region.

Thus, one photosensor from the plurality of photosensors is selected and driven and the other photosensors are not driven. For example, the supply of electric power or a control signal to the photosensors which are not driven stops, so that consumption of electric power can be reduced. As a result, a novel information processing device with high convenience or high reliability can be provided.

(5) Another embodiment of the present invention is the above-described information processing device that includes a display portion.

The housing has a function of housing the display portion.

The display portion includes a selection circuit and a display panel.

The display panel is electrically connected to the selection circuit.

The selection circuit has a function of receiving control information, image information, or background information. The selection circuit has a function of supplying the image information or the background information based on the control information.

The display panel includes a signal line and a pixel.

The signal line has a function of receiving an image signal based on the image information or the background information.

The pixel is electrically connected to the signal line. The pixel includes a pixel circuit, a first display element, and a second display element.

The first display element is electrically connected to the pixel circuit and the second display element is electrically connected to the pixel circuit.

Thus, the image information or the background information can be displayed on the first display element or the second display element on the basis of the control information. As a result, a novel information processing device with high convenience or high reliability can be provided.

(6) Another embodiment of the present invention is the above-described information processing device that includes a group of a plurality of pixels, another group of a plurality of pixels, and a scan line.

The pixel is included in the group of pixels. The group of pixels are arranged in a row direction.

The pixel is also included in the another group of pixels. The another group of pixels are arranged in a column direction intersecting the row direction.

The scan line is electrically connected to the group of pixels.

The another group of pixels are electrically connected to the signal line.

(7) Another embodiment of the present invention is the above-described information processing device in which the pixel includes a second conductive film, a first conductive film, and a first insulating film.

The second conductive film is electrically connected to the pixel circuit.

The first conductive film includes a region overlapping with the second conductive film.

The first insulating film includes a region between the second conductive film and the first conductive film. The first insulating film includes an opening in the region between the first conductive film and the second conductive film.

The first conductive film is electrically connected to the second conductive film in the opening.

The first display element is electrically connected to the first conductive film, includes a reflective film, and has a function of controlling the intensity of light reflected by the reflective film.

The second display element has a function of emitting light toward the second insulating film.

The reflective film has a shape including a region that does not block light emitted from the second display element.

(8) Another embodiment of the present invention is the above-described information processing device in which the reflective film includes one or a plurality of openings and the second display element has a function of emitting light toward the opening.

(9) Another embodiment of the present invention is the above-described information processing device in which the second display element is provided so that display using the second display element can be seen from part of a region from which display using the first display element can be seen.

(10) Another embodiment of the present invention is the above-described information processing device that includes an input portion.

The input portion includes a region overlapping with the display panel and includes a control line, a sensor signal line, and a sensing element.

The sensing element is electrically connected to the control line and the sensor signal line.

The control line has a function of supplying a control signal.

The sensing element receives the control signal and has a function of supplying the control signal and a sensor signal which changes in accordance with a distance between the sensing element and an object approaching the region overlapping with the display panel.

The sensor signal line has a function of receiving the sensor signal.

The sensing element has a light-transmitting property and includes a first electrode and a second electrode.

The first electrode is electrically connected to the control line.

The second electrode is electrically connected to the sensor signal line. The second electrode is provided so that an electric field that is partly blocked by the object approaching the region overlapping with the display panel is generated between the first electrode and the second electrode.

(11) Another embodiment of the present invention is the above-described information processing device that includes at least one of a keyboard, a hardware button, a pointing device, a touch sensor, an imaging device, an audio input device, and a viewpoint input device.

Thus, the information processing device can identify the intensity of light received by the housing of the information processing device and operate under a usage environment. Furthermore, for example, the information processing device can identify a region which is hardly blocked by a hand or the like which holds the housing, and can identify the intensity of the light received by the region and operate. As a result, a novel information processing device with high convenience or high reliability can be provided.

Although the block diagram attached to this specification shows components classified by their functions in independent blocks, it is difficult to classify actual components according to their functions completely and it is possible for one component to have a plurality of functions.

In this specification, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, although connection relation of the transistor is described assuming that the source and the drain are fixed for convenience in some cases, actually, the names of the source and the drain interchange with each other depending on the relation of the potentials.

Note that in this specification, a “source” of a transistor means a source region that is part of a semiconductor film functioning as an active layer or a source electrode connected to the semiconductor film. Similarly, a “drain” of a transistor means a drain region that is part of the semiconductor film or a drain electrode connected to the semiconductor film. A “gate” means a gate electrode.

Note that in this specification, a state in which transistors are connected to each other in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification, the term “connection” means electrical connection and corresponds to a state where current, voltage, or a potential can be supplied or transmitted. Accordingly, connection means not only direct connection but also indirect connection through a circuit element such as a wiring, a resistor, a diode, or a transistor so that current, a potential, or voltage can be supplied or transmitted.

In this specification, even when different components are connected to each other in a circuit diagram, there is actually a case where one conductive film has functions of a plurality of components such as a case where part of a wiring serves as an electrode. The term “connection” also means such a case where one conductive film has functions of a plurality of components.

Further, in this specification, one of a first electrode and a second electrode of a transistor refers to a source electrode and the other refers to a drain electrode.

According to one embodiment of the present invention, a novel information processing device that is highly convenient or reliable can be provided. Alternatively, a novel information processing device or a novel semiconductor device can be provided.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A and 1B illustrate a structure and a use state of an information processing device of one embodiment.

FIG. 2 is a block diagram illustrating a structure of an information processing device of one embodiment.

FIGS. 3A and 3B illustrate a structure and an attitude of an information processing device of one embodiment.

FIG. 4 is a block diagram illustrating a structure of a display portion in an information processing device of one embodiment.

FIGS. 5A and 5B are block diagrams illustrating a structure of a display portion in an information processing device of one embodiment.

FIG. 6 is a circuit diagram illustrating a pixel circuit of a display portion in an information processing device of one embodiment.

FIGS. 7A and 7B are flow charts illustrating a method for driving an information processing device of one embodiment.

FIG. 8 is a flow chart illustrating a method for driving an information processing device of one embodiment.

FIG. 9 is a flow chart illustrating a method for driving an information processing device of one embodiment.

FIGS. 10A, 10B-1, 10B-2, and 10C illustrate a structure of a touch panel in an information processing device of one embodiment.

FIGS. 11A and 11B illustrate a pixel structure of a display panel of a touch panel in an information processing device of one embodiment.

FIGS. 12A and 12B are cross-sectional views illustrating a cross-sectional structure of a touch panel in an information processing device of one embodiment.

FIGS. 13A and 13B are cross-sectional views illustrating a cross-sectional structure of a touch panel in an information processing device of one embodiment.

FIGS. 14A to 14C are circuit diagrams illustrating a shape of a reflective film of a display panel of an information processing device of one embodiment.

FIG. 15 is a block diagram illustrating a structure of an input portion of an information processing device of one embodiment.

FIGS. 16A, 16B-1, and 16B-2 illustrate a structure of an input/output device of one embodiment.

FIGS. 17A and 17B are cross-sectional views illustrating a cross-sectional structure of an input/output device of one embodiment.

FIG. 18 is a cross-sectional view illustrating a cross-sectional structure of an input/output device of one embodiment.

FIGS. 19A to 19C are cross-sectional views illustrating a semiconductor device.

FIGS. 20A and 20B are cross-sectional views illustrating a semiconductor film.

FIGS. 21A and 21B illustrate energy bands.

FIGS. 22A to 22C are a cross-sectional view and circuit diagrams illustrating a structures of a semiconductor device of one embodiment.

FIG. 23 is a block diagram illustrating a structure of a CPU of one embodiment.

FIG. 24 is a circuit diagram illustrating a structure of a flip flop circuit of one embodiment.

FIGS. 25A to 25H each illustrate a structures of electronic devices of one embodiment.

### DETAILED DESCRIPTION OF THE INVENTION

An information processing device of one embodiment of the present invention includes a housing, an attitude sensor, a plurality of photosensors, and an arithmetic device. The attitude sensor has a function of sensing an attitude of the housing and a function of supplying attitude information based on of the attitude. The housing includes a plurality of regions. The photosensors have a function of measuring illuminance in each of the plurality of regions and a function of supplying illuminance information based on the illuminance. The arithmetic device has a function of selecting one region on the basis of the attitude information and a function of operating on the basis of the illuminance information of the selected region.

Thus, the information processing device can identify the intensity of light received by the housing of the information processing device and operate under a usage environment. Furthermore, for example, the information processing device can identify a region which is hardly blocked by a hand or the like which holds the housing, and can identify the intensity of the light received by the region and operate. As a result, a novel information processing device with high convenience or high reliability can be provided.

Embodiments will be described in detail with reference to the drawings. Note that the present invention is not limited to the following description. It will be readily appreciated by those skilled in the art that modes and details of the present invention can be modified in various ways without departing from the spirit and scope of the present invention. Thus, the present invention should not be construed as being limited to the description in the following embodiments and example. Note that in structures of the present invention described below, the same portions or portions having similar functions are denoted by the same reference numerals in different drawings, and a description thereof is not repeated.

### Embodiment 1

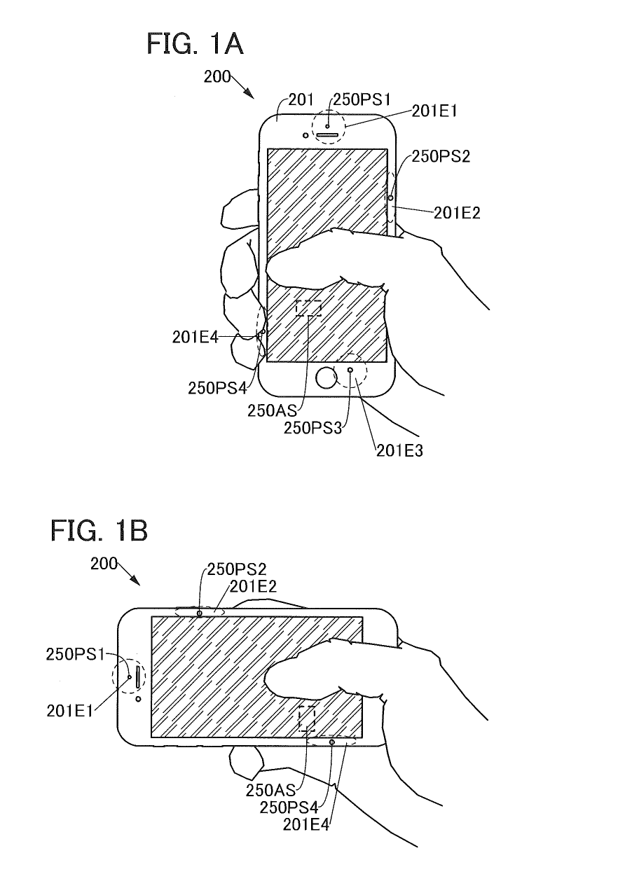

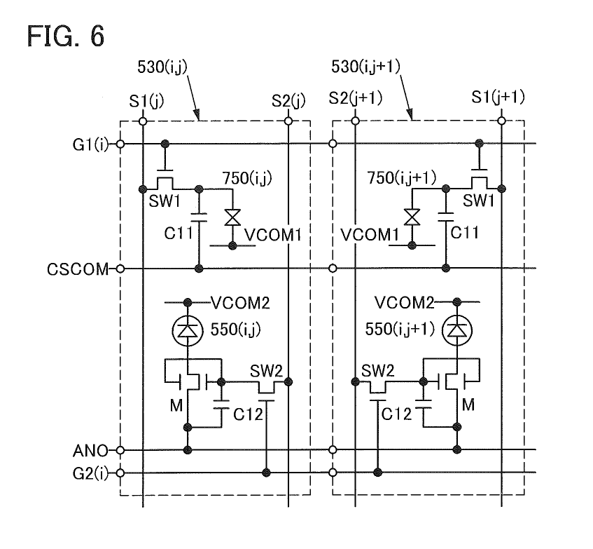

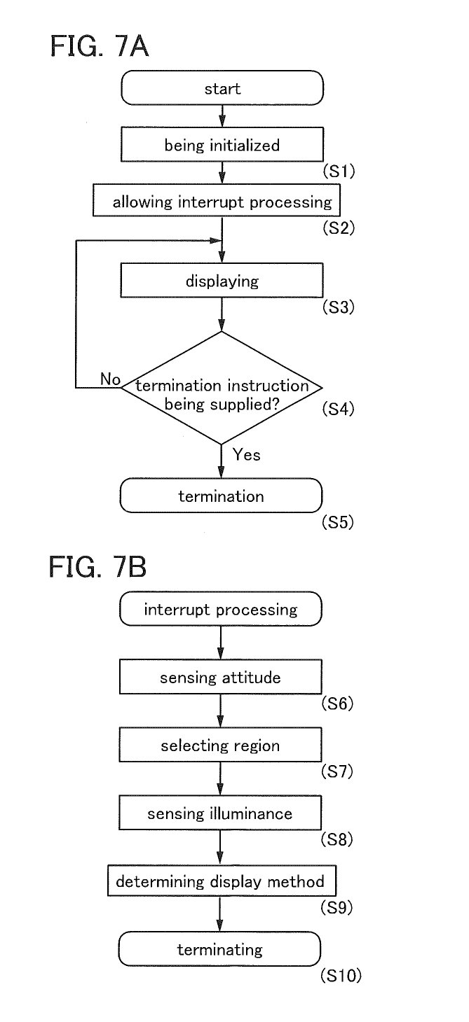

In this embodiment, the structure of the information processing device of one embodiment of the present invention will be described with reference to FIGS. 1A and 1B, FIG. 2, FIGS. 3A and 3B, FIG. 4, FIGS. 5A and 5B. FIG. 6, FIGS. 7A and 7B, FIG. 8, and FIG. 9.

FIGS. 1A and 1B are schematic views illustrating a structure and a use state of the information processing device of one embodiment of the present invention. FIG. 1A is a schematic view illustrating a use state of the information processing device in a vertical direction, and FIG. 1B is a schematic view illustrating a use state of the information processing device in a horizontal position.

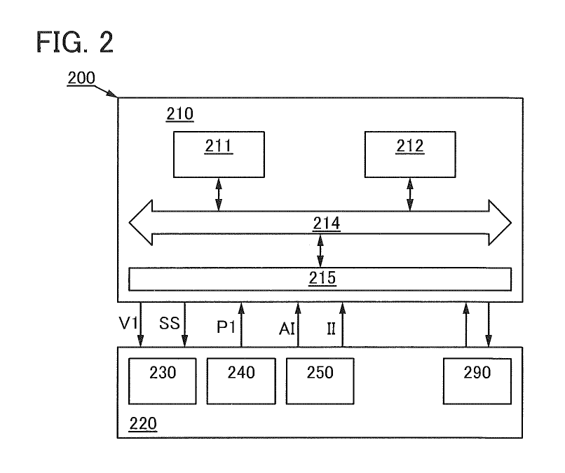

FIG. 2 is a block diagram illustrating a structure of the information processing device of one embodiment of the present invention.

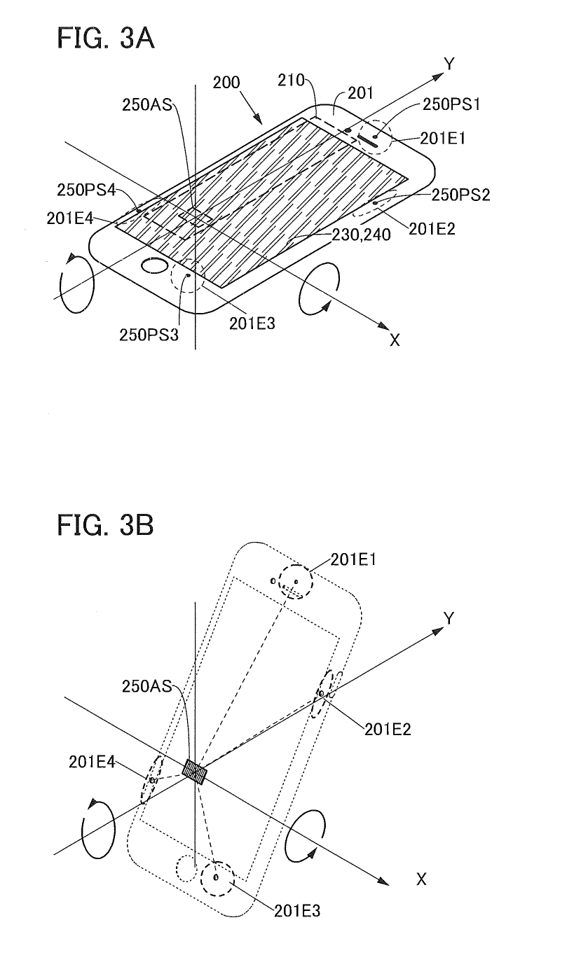

FIGS. 3A and 3B illustrate a structure of the information processing device of one embodiment of the present invention. FIG. 3A is a projection view illustrating an external appearance of the information processing device of one embodiment of the present invention, and FIG. 3B is a schematic view illustrating the relationship among the attitude of the information processing device in FIG. 3A, the attitude sensor, and the plurality of regions included in the housing.

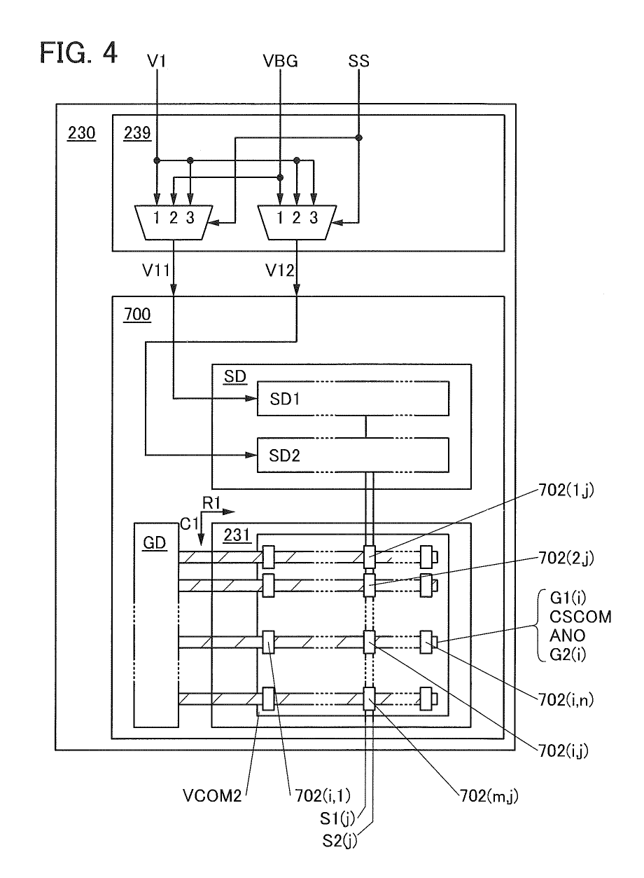

FIG. 4 is a block diagram illustrating a structure of a display portion of the information processing device of one embodiment of the present invention.

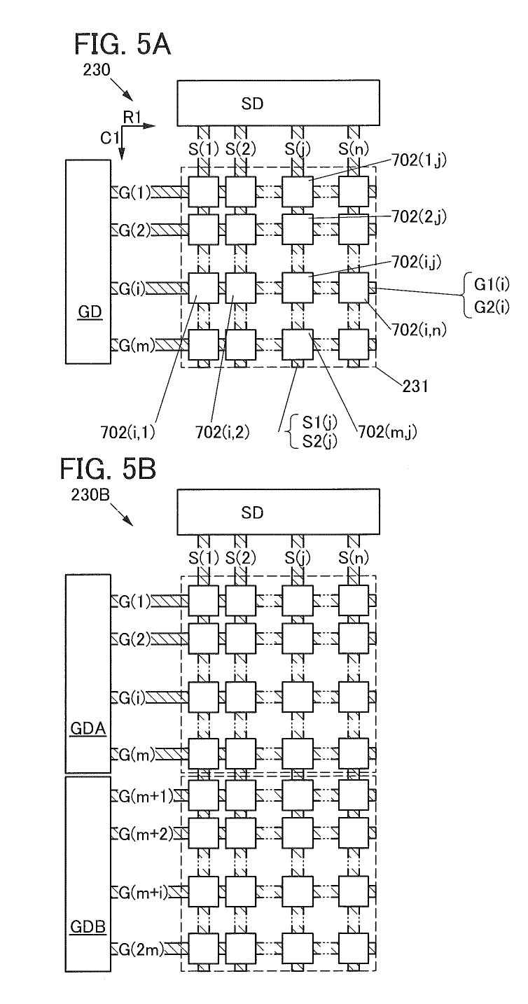

FIGS. 5A and 5B are block diagrams illustrating a structure of a display portion of the information processing device of one embodiment of the present invention. FIG. 5A is a block diagram illustrating a structure of the display portion of the information processing device, and FIG. 5B is a block diagram illustrating a different structure from FIG. 5A.

FIG. 6 is a circuit diagram illustrating a structure of a pixel circuit included in the input/output device of one embodiment of the present invention.

FIGS. 7A and 7B are flow charts illustrating the program of one embodiment of the present invention. FIG. 7A is a flow chart illustrating main processing of the program of one embodiment of the present invention, and FIG. 7B is a flow chart illustrating interrupt processing.

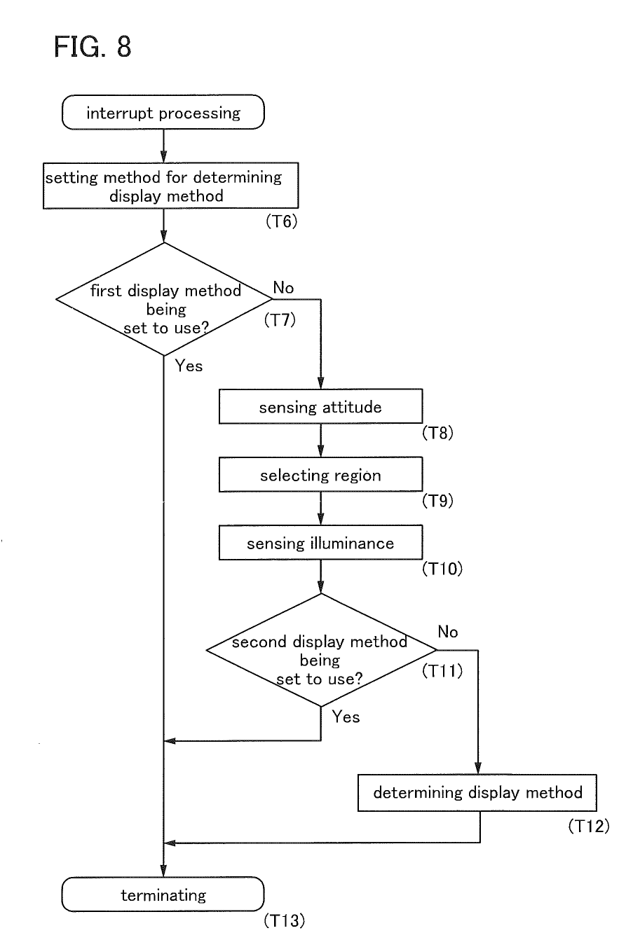

FIG. 8 is a flow chart illustrating interrupt processing of the program of one embodiment of the present invention.

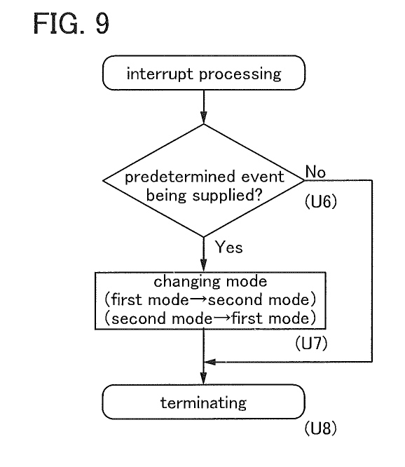

FIG. 9 is a flow chart illustrating interrupt processing of the program of one embodiment of the present invention.

### <Structure Example 1 of Information Processing Device>

An information processing device 200 described in this embodiment includes a housing 201, an attitude sensor 250AS, photosensors, and an arithmetic device 210 (see FIG. 1A).

The attitude sensor 250AS has a function of sensing the attitude of the housing 201 and a function of supplying attitude information AI based on the attitude (see FIG. 2).

The housing 201 includes a plurality of regions. For example, the housing 201 includes regions 201E1 to 201E4 (see FIG. 1A).

The photosensors have a function of measuring illuminance in each of the plurality regions and a function of supplying illuminance information II based on the illuminance (see FIG. 2).

For example, a photosensor 250PS1 has a function of measuring illuminance in the region 201E1 and a function of supplying illuminance information II based on the illuminance. A photosensor 250PS2 has a function of measuring illuminance in the region 201E2 and a function of supplying illuminance information II based on the illuminance. A photosensor 250PS3 has a function of measuring illuminance in the region 201E3 and a function of supplying illuminance information II based on the illuminance. A photosensor 250PS4 has a function of measuring illuminance in the region 201E4 and a function of supplying illuminance information II based on the illuminance.

The arithmetic device 210 has a function of selecting at least one region from the plurality of regions on the basis of the attitude information AI and a function of operating on the basis of the illuminance information II of the selected region (see FIG. 2).

Thus, the information processing device can identify the intensity of light received by the housing of the information processing device and operate under a usage environment. Furthermore, for example, the information processing device can identify a region which is hardly blocked by a hand or the like which holds the housing, and can identify the intensity of light received by the region and operate. As a result, a novel information processing device with high convenience or high reliability can be provided.

The information processing device 200 described in this embodiment is the above-described information processing device in which the arithmetic device 210 has a function of selecting a region located on the top among the plurality of regions.

For example, when the region 201E1 is located on the top among the regions 201E1 to 201E4, the arithmetic device 210 selects the region 201E1 (see FIG. 3B).

For example, a sensor which measures slopes of two axis can be used as the attitude sensor 250AS. Specifically, an acceleration sensor which senses a slope with respect to an X axis and a slope with respect to a Y axis can be used as the attitude sensor 250AS (see FIG. 3A).

For example, when the attitude sensor 250AS is fixed to the housing 201, the arithmetic device 210 can identify the positions of the regions 201E1 to 201E4 with use of a polar coordinates system in which the attitude sensor 250AS is located on the origin. Thus, the arithmetic device 210 can identify a region located on the top among the plurality of regions.

For example, in the housing 201 which is tilted to the Y axis by 60 degrees, the region 201E1 is located on a higher position than the other regions 201E2 to 201E4 (see FIG. 3B).

Note that a region which is located on the right side, the left side, or the bottom side of the housing 201 is often held by the user of the information processing device 200 when the user uses the information processing device 200. Furthermore, the region of the housing 201 located on the top is hardly blocked by the user's hand or the like which holds the information processing device 200 (see FIGS. 1A and 1B).

Thus, the information processing device can identify the intensity of light received by the region located on the top among the plurality of regions of the housing and operate. Furthermore, the information processing device can select a region which is hardly blocked by a hand or the like which holds the housing such as the region located on the top among the plurality of regions included in the housing, and can identify the intensity of light received by the region and operate. As a result, a novel information processing device with high convenience or high reliability can be provided.

The information processing device 200 described in this embodiment includes a plurality of photosensors such as photosensors 250PS1 to 250PS4. The regions 201E1 to 201E4 included in the housing include the photosensors 250PS1 to 250PS4, respectively. Each photosensor supplies illuminance information II in the region where the photosensors are provided.

Furthermore, the information processing device 200 described in this embodiment includes a sensor portion 250. The sensor portion 250 has a function of driving the photosensor of the selected region (see FIG. 2).

Thus, one photosensor from the plurality of photosensors is selected and driven and the other photosensors are not driven. For example, the supply of electric power or a control signal to the photosensors which are not driven stops, so that consumption of electric power can be reduced. As a result, a novel information processing device with high convenience or high reliability can be provided.

Furthermore, the information processing device 200 described in this embodiment includes a display portion 230 (see FIG. 4).

The housing 201 has a function of housing the display portion 230. Alternatively, the housing 201 has a function of supporting the display portion 230 (see FIG. 3A).

The display portion 230 includes a selection circuit 239 and a display panel 700 (see FIG. 4).

The display panel 700 is electrically connected to the selection circuit 239, and the selection circuit 239 has a function of receiving control information SS, image information V1, or background information VBG. Note that image information displayed on the display panel 700 can be used as the image information V1. As the background information VBG, a black image, a white image, an image of a predetermined color, or a background image with a predetermined pattern can be used, for example. Furthermore, information which includes part of or all of the image information V1 can be used as the background information VBG.

The selection circuit 239 has a function of supplying the image information V1 or the background information VBG based on the control information SS.

The display panel 700 includes a signal line S1(j), a signal line S2(j), and a pixel 702(i, j).

The pixel 702(i, j) is electrically connected to the signal line S1(j) and the signal line S2(j).

The signal line S1(j) has a function of receiving an image signal based on the image information V1 or the background information VBG, and the signal line S2(j) has a function of receiving an image signal based on the image information V1 or the background information VBG.

The pixel 702(i, j) includes a pixel circuit 530(i, j), a first display element 750(i, j), and a second display element 550(i, j) (see FIG. 6).

The first display element 750(i, j) is electrically connected to the pixel circuit 530(i, j) and the second display element 550(i, j) is electrically connected to the pixel circuit 530(i, j).

The information processing device described in this embodiment is configured to include the selection circuit supplying the image information or the background information based on the control information. Thus, the image information or the background information can be displayed on the first display element or the second display element on the basis of the control information. As a result, a novel information processing device with high convenience or high reliability can be provided.

The information processing device 200 described in this embodiment includes one group of pixels 702(i, 1) to 702(i, n), another group of pixels 702(1, j) to 702(m, j), and a scan line G1(i) (see FIG. 4). Note that i is an integer greater than or equal to 1 and less than or equal to m, j is an integer greater than or equal to 1 and less than or equal to n, and each of m and n is an integer greater than or equal to 1.

The one group of pixels 702(i, 1) to 702(i, n) include the pixel 702(i, j). The one group of pixels 702(i, 1) to 702(i, n) are arranged in a row direction (indicated by an arrow R1 in the drawing).

The other group of pixels 702(1, j) to 702(m, j) include the pixel 702(i, j). The other group of pixels 702(1, j) to 702(m, j) are arranged in a column direction (indicated by an arrow C1 in the drawing) that intersects with the row direction.

The scan line G1(i) is electrically connected to the plurality of pixels 702(i, 1) to 702(i, n).

The another plurality of pixels 702(1, j) to 702(m, j) are electrically connected to the signal line S1(j).

Individual components included in the information processing device will be described below. Note that these components cannot be clearly distinguished and one component may also serve as another component or include part of another component. For example, a touch panel in which a touch sensor is provided so as to overlap with a display panel serves as an input portion as well as a display portion.

### Structure Example

The information processing device of one embodiment of the present invention includes the housing 201, the attitude sensor 250AS, the photosensors 250PS1 to 250PS4, or the arithmetic device 210.

The housing 201 includes the regions 201E1 to 201E4.

The arithmetic device 210 includes an arithmetic portion 211, a memory portion 212, a transmission path 214, or an input/output interface 215. The arithmetic device 210 has a function of receiving a positional information P1 or a sensed information and a function of supplying the image information V1. For example, the arithmetic device 210 has a function of operating on the basis of the positional information P1 or the sensed information.

The information processing device of one embodiment of the present invention includes an input/output device 220.

The input/output device 220 includes the display portion 230, an input portion 240, the sensor portion 250, and a communication portion 290. The input/output device 220 has a function of receiving the image information V1 or the control information SS and a function of supplying the positional information P1 or the sensed information.

The sensor portion 250 includes the attitude sensor 250AS and the photosensors 250PS1 to 250PS4.

### <<Information Processing Device>>

The information processing device of one embodiment of the present invention includes the arithmetic device 210 or the input/output device 220.

### <<Arithmetic Device 210>>

The arithmetic device 210 includes the arithmetic portion 211 and the memory portion 212. The arithmetic device 210 further includes the transmission path 214 and the input/output interface 215 (see FIG. 2).

### <<Arithmetic Portion 211>>

The arithmetic portion 211 is configured to, for example, execute a program. For example, a CPU described in Embodiment 5 can be used. In that case, power consumption can be sufficiently reduced.

### <<Memory Portion 212>>

The memory portion 212 is configured to, for example, store the program executed by the arithmetic portion 211, initial information, setting information, an image, or the like.

Specifically, a hard disk, a flash memory, a memory including a transistor including an oxide semiconductor, or the like can be used.

### <<Input/Output Interface 215 and Transmission Path 214>>

The input/output interface 215 includes a terminal or a wiring and is configured to supply and receive information. For example, the input/output interface 215 can be electrically connected to the transmission path 214 and the input/output device 220.

The transmission path 214 includes a wiring and is configured to supply and receive information. For example, the transmission path 214 can be electrically connected to the input/output interface 215. In addition, the transmission path 214 can be electrically connected to the arithmetic portion 211, the memory portion 212, or the input/output interface 215.

### <<Input/Output Device 220>>

The input/output device 220 includes the display portion 230, the input portion 240, the sensor portion 250, or the communication portion 290. For example, the touch panel described in Embodiment 2 can be used for the input/output device 220. In that case, power consumption can be reduced.

### <<Display Portion 230>>

The display portion 230 includes the selection circuit 239, a driving circuit GD, a driving circuit SD, and the display panel 700 (see FIG. 4). The display panel 700 includes a display region 231 (see FIG. 5A). Note that the display panel includes the driving circuit GD or the driving circuit SD.

### <<Selection Circuit 239>>

In the selection circuit 239, a first multiplexer and a second multiplexer can be used, for example (see FIG. 4). The first multiplexer and the second multiplexer have a function of operating on the basis of the control information SS.

The first multiplexer includes a first input portion and a third input portion to which the image information V1 is supplied and a second input portion to which the background information VBG is supplied, and receives the control information SS. The first multiplexer outputs the image information V1 when receiving a first-status or third-status control information SS and outputs the background information VBG when receiving a second-status control information SS. Note that the information output from the first multiplexer is referred to as the information V11.

The second multiplexer includes a first input portion to which the background information VBG is supplied and a second input portion and a third input portion to which the image information V1 is supplied, and receives the control information SS. The second multiplexer outputs the background information VBG when receiving the first-status control information SS and outputs the image information V1 when receiving the second-status or third-status control information SS. Note that the information output from the second multiplexer is referred to as the information V12.

### <<Display Region 231>>

The display region 231 includes one group of pixels 702(i, 1) to 702(i, n), another group of pixels 702(1, j) to 702(m, j), a scan line G1(i), and a scan line G2(i) (see FIG. 5A). Note that i is an integer greater than or equal to 1 and less than or equal to m, j is an integer greater than or equal to 1 and less than or equal to n, and each of m and n is an integer greater than or equal to 1.

The one group of pixels 702(i, 1) to 702(i, n) include the pixel 702(i, j) and are provided in the row direction (the direction indicated by the arrow R1 in the drawing).

The another group of pixels 702(1, j) to 702(m, j) include the pixel 702(i, j) and are provided in the column direction (the direction indicated by the arrow C1 in the drawing) that intersects the row direction.

The scan line G1(i) and the scan line G2(i) are electrically connected to the group of pixels 702(i, 1) to 702(i, n) provided in the row direction.

The signal line S1(j) and the signal line S2 (j) are electrically connected to the another group of the pixels 702(1, j) to 702(m, j) arranged in the column direction.

The display portion 230 can include a plurality of driver circuits. For example, a display portion 230B can include a driver circuit GDA and a driver circuit GDB (see FIG. 5B).

### <<Driver Circuit GD>>

The driver circuit GD has a function of supplying a selection signal based on the control information.

For example, the driver circuit GD has a function of supplying a selection signal to one scan line at a frequency of 30 Hz or higher, preferably 60 Hz or higher, in accordance with the control information. Accordingly, moving images can be smoothly displayed.

For example, the driver circuit GD has a function of supplying a selection signal to one scan line at a frequency of lower than 30 Hz, preferably lower than 1 Hz, further preferably less than once per minute, in accordance with the control information. Accordingly, a still image can be displayed while flickering is suppressed.

For example, in the case where a plurality of driver circuits is provided, the driver circuits GDA and GDB may supply the selection signals at different frequencies. Specifically, the selection signal can be supplied at a higher frequency to a region on which moving images are smoothly displayed than to a region on which a still image is displayed in a state where flickering is suppressed.

### <<Driver Circuit SD, Driver Circuit SD1, Driver Circuit SD2>>

The driver circuit SD includes a driver circuit SD1 and a driver circuit SD2. The driver circuit SD1 has a function of supplying an image signal based on the information V11. The driver circuit SD2 has a function of supplying an image signal based on the information V12 (see FIG. 4).

The driver circuit SD1 has a function of generating an image signal to be supplied to a pixel circuit electrically connected to a reflective display element, for example. Specifically, the driver circuit SD1 has a function of generating a signal whose polarity is inverted. Thus, for example, a reflective liquid crystal display element can be driven.

The driver circuit SD2 has a function of generating an image signal to be supplied to a pixel circuit electrically connected to a light-emitting element, for example.

For example, any of a variety of sequential circuits, such as a shift register, can be used as the driver circuit SD.

For example, an integrated circuit in which the driver circuit SD1 and the driver circuit SD2 are integrated can be used as the driver circuit SD. Specifically, an integrated circuit formed on a silicon substrate can be used as the driver circuit SD.

For example, the driver circuit SD can be mounted on a terminal by a chip on glass (COG) method. Specifically, an anisotropic conductive film can be used to mount an integrated circuit on the terminal. Alternatively, a chip on film (COF) may be used to mount an integrated circuit on the terminal.

<<Pixel 702(i,j)>>

The pixel 702(i, j) includes the first display element 750(i, j), the second display element 550(i, j), and the pixel circuit. The pixel circuit has a function of driving the first display element 750(i, j) and the second display element 550(i, j).

<<First Display Element 750(i, j)>>

For example, a display element having a function of controlling transmission or reflection of light can be used as the first display element 750(i, j). Specifically, a reflective liquid crystal display element can be used as the first display element 750(i, j). Alternatively, a MEMS shutter display element and the like can be used. The use of a reflective display element can reduce power consumption of a display panel.

<<Second Display Element 550(i, j)>>

A display element having a function of emitting light can be used as the second display element 550(i, j), for example. Specifically, an organic EL element and the like can be used.

### <<Pixel Circuit>>

A pixel circuit including a circuit that has a function of driving the first display element 750(i, j) and the second display element 550(i, j) can be used.

A switch, a transistor, a diode, a resistor, an inductor, a capacitor, or the like can be used in the pixel circuit.

For example, one or a plurality of transistors can be used as a switch. Alternatively, a plurality of transistors connected in parallel, in series, or in combination of parallel connection and series connection can be used as a switch.

### <<Transistor>>

For example, semiconductor films formed at the same step can be used for transistors in the driver circuit and the pixel circuit.

For example, bottom-gate transistors, top-gate transistors, or the like can be used.

A manufacturing line for a bottom-gate transistor including amorphous silicon as a semiconductor can be easily remodeled into a manufacturing line for a bottom-gate transistor including an oxide semiconductor as a semiconductor, for example. Furthermore, for example, a manufacturing line for a top-gate transistor including polysilicon as a semiconductor can be easily remodeled into a manufacturing line for a top-gate transistor including an oxide semiconductor as a semiconductor. In any reconstruction, a conventional manufacturing line can be effectively used.

For example, a transistor including a semiconductor containing an element of Group 14 can be used. Specifically, a semiconductor containing silicon can be used for a semiconductor film. For example, single crystal silicon, polysilicon, microcrystalline silicon, amorphous silicon, or the like can be used for the semiconductor film of the transistor.

Note that the temperature for forming a transistor using polysilicon as a semiconductor is lower than the temperature for forming a transistor using single crystal silicon as a semiconductor.

In addition, the transistor using polysilicon as a semiconductor has higher field-effect mobility than the transistor using amorphous silicon as a semiconductor, and therefore a pixel including the transistor using polysilicon can have a high aperture ratio. Moreover, pixels arranged at high resolution, a gate driver circuit, and a source driver circuit can be formed over the same substrate. As a result, the number of components included in an electronic device can be reduced.

In addition, the transistor using polysilicon as a semiconductor has higher reliability than the transistor using amorphous silicon as a semiconductor.

For example, a transistor including an oxide semiconductor can be used. Specifically, an oxide semiconductor containing indium or an oxide semiconductor containing indium, gallium, and zinc can be used for a semiconductor film.

For example, a transistor having a lower leakage current in an off state than a transistor that uses amorphous silicon in a semiconductor film can be used. Specifically, a transistor that uses an oxide semiconductor in a semiconductor film can be used.

A pixel circuit including the transistor that uses an oxide semiconductor in the semiconductor film can hold an image signal for a longer time than a pixel circuit including the transistor that uses amorphous silicon in a semiconductor film. Specifically, the selection signal can be supplied at a frequency of lower than 30 Hz, preferably lower than 1 Hz, further preferably less than once per minute while flickering is suppressed. Consequently, eyestrain on a user of the information processing device can be reduced, and power consumption for driving can be reduced.

Alternatively, for example, a transistor including a compound semiconductor can be used. Specifically, a semiconductor containing gallium arsenide can be used in a semiconductor film.

For example, a transistor including an organic semiconductor can be used. Specifically, an organic semiconductor containing any of polyacenes and graphene can be used in the semiconductor film.

### <<Input Portion 240>>

A variety of human interfaces or the like can be used as the input portion 240 (see FIG. 2).

For example, a keyboard, a mouse, a touch sensor, a microphone, a camera, or the like can be used as the input portion 240. Note that a touch sensor having a region overlapping with the display portion 230 can be used. An input/output device that includes the display portion 230 and a touch sensor having a region overlapping with the display portion 230 can be referred to as a touch panel or a touch screen.

For example, a user can make various gestures (e.g., tap, drag, swipe, and pinch in) using his/her finger as a pointer on the touch panel.

The arithmetic device 210, for example, analyzes information on the position, track, or the like of the finger on the touch panel and determines that a specific gesture is supplied when the analysis results meet predetermined conditions. Therefore, the user can supply a certain operation instruction associated with a certain gesture by using the gesture.

For instance, the user can supply a “scrolling instruction” for changing a portion where image information is displayed by using a gesture of touching and moving his/her finger on the touch panel.

### <<Sensor Portion 250>>

The sensor portion 250 has a function of sensing the surroundings and supplying the sensing information such as illuminance information, attitude information, pressure information, and positional information.

For example, a photosensor, an attitude sensor, an acceleration sensor, a direction sensor, a global positioning system (GPS) signal receiving circuit, a pressure sensor, a temperature sensor, a humidity sensor, a camera, or the like can be used as the sensor portion 250.

### <<Communication Portion 290>>

The communication portion 290 has a function of supplying and acquiring information to/from a network.

### <<Program>>

The program of one embodiment of the present invention has the following steps (see FIG. 7A).

### [First Step]

In the first step, setting is initialized (see S1 in FIG. 7A).

For example, predetermined image information which is to be displayed on start-up and information for identifying a predetermined mode of displaying the image information and a predetermined method of displaying the image information are acquired from the memory portion 212. Specifically, predetermined still image information or predetermined moving image information can be used as the predetermined image information. Furthermore, a first mode or a second mode can be used as the predetermined mode. Furthermore, a first display method, a second display method, or a third display method can be used as the predetermined display method.

### [Second Step]

In the second step, interrupt processing is allowed (see S2 in FIG. 7A). Note that an arithmetic device allowed to execute the interrupt processing can perform the interrupt processing in parallel with the main processing. The arithmetic device that has returned from the interrupt processing to the main processing can reflect the results of the interrupt processing in the main processing.

The arithmetic device may execute the interrupt processing when a counter has an initial value, and the counter may be set at a value other than the initial value when the arithmetic device returns from the interrupt processing. Thus, the interrupt processing is ready to be executed after the program is started up.

### [Third Step]

In a third step, image information is displayed in the predetermined mode or the predetermined display method selected in the first step or the interrupt processing (see S3 in FIG. 7A). Note that the predetermined mode identifies a mode for displaying the image information, and the predetermined display method identifies a method for displaying the image information.

For example, two different methods for displaying the image information V1 or the background information VBG can be associated with the first mode and the second mode. Thus, a display method can be selected on the basis of the selected mode.

For example, three different methods for displaying the image information V1 or the background information VBG can be associated with the first method to the third method.

### <<First Mode>>

Specifically, a method of supplying selection signals to a scan line at a frequency of 30 Hz or more, preferably 60 Hz or more, and performing display in accordance with the selection signals can be associated with the first mode.

The supply of selection signals at a frequency of 30 Hz or more, preferably 60 Hz or more, can display a smooth moving image.

For example, when an image is refreshed at a frequency of 30 Hz or more, preferably 60 Hz or more, an image smoothly following the user's operation can be displayed on the information processing device 200 the user is operating.

### <<Second Mode>>

Specifically, a method of supplying selection signals to a scan line at a frequency of less than 30 Hz, preferably less than 1 Hz, further preferably once a minute and performing display in accordance with the selection signals can be associated with the second mode.

The supply of selection signals at a frequency of less than 30 Hz, preferably less than 1 Hz, further preferably once a minute, can perform display with flickers reduced. Furthermore, power consumption can be reduced.

For example, when a light-emitting element is used as the second display element, the light-emitting element can be configured to emit light in a pulsed manner so as to display image information. Specifically, an organic EL element can be configured to emit light in a pulsed manner, and its afterglow can be used for display. The organic EL element has excellent frequency characteristics; thus, time for driving the light-emitting element can be shortened, and thus power consumption can be reduced in some cases. Alternatively, heat generation can be inhibited, and thus the deterioration of the light-emitting element can be suppressed in some cases.

For example, when the information processing device 200 is used for a clock or watch, the display can be refreshed at a frequency of once a second, once a minute, or the like.

### <<First Display Method>>

Specifically, a method in which the first display element 750(i, j) is used to display image information can be used as the first display method. Thus, for example, the power consumption can be reduced. In addition, image information with high contrast can be favorably displayed in a bright environment.

### <<Second Display Method>>

Specifically, a method in which the second display element 550(i, j) is used to display image information can be used as the second display method. Thus, for example, an image can be favorably displayed in a dark environment. Furthermore, a photograph and the like can be displayed with favorable color reproducibility. In addition, a moving image which moves quickly can be displayed smoothly.

Note that the display brightness of the image information V1 utilizing the second display element 550(i, j) can be determined on the basis of the illuminance information II. For example, when illuminance is higher than or equal to 1000 lux and less than 10000 lux, the image information is displayed with use of the second display method to be brighter than the case where the illuminance is less than 1000 lux.

### <<Third Display Method>>

Specifically, a method in which the first display element 750(i, j) and the second display element 550(i, j) are used to display image information can be used as the third display method. Thus, for example, the power consumption can be further reduced. Thus, for example, an image can be favorably displayed in a dark environment. Furthermore, a photograph and the like can be displayed with favorable color reproducibility. In addition, a moving image which moves quickly can be displayed smoothly.

### [Fourth Step]

In a fourth step, the next step is determined as follows: a fifth step is selected when a termination instruction has been supplied, whereas the third step is selected when the termination instruction has not been supplied (see S4 in FIG. 7A).

For example, the termination instruction supplied in the interrupt processing can be used to determine the next step.

### [Fifth Step]

In the fifth step, the program terminates (see S5 in FIG. 7A).

### <<Interrupt Processing>>

The interrupt processing includes the following sixth to tenth steps (see FIG. 7B).

### [Sixth Step]

In the sixth step, the attitude of the information processing device is sensed (see S6 in FIG. 7B). For example, an average value of the slopes of the housing 201 sensed during the predetermined period of time can be used as an index indicating the attitude. Specifically, the predetermined period of time may be longer than 0 seconds and shorter than 0.1 seconds, longer than or equal to 0.1 seconds and shorter than 0.5 seconds, longer than or equal to 0.5 seconds and shorter than 1 second, longer than or equal to 1 second and shorter than 5 seconds, or longer than or equal to 5 seconds.

### [Seventh Step]

In the seventh step, a region is selected on the basis of the sensed attitude (see S7 in FIG. 7B). For example, a region on the top is selected.

### [Eighth Step]

In the eighth step, the illuminance of the selected region is sensed by driving the photosensor for measuring the illuminance of the selected region (see S8 in FIG. 7B).

### [Ninth Step]

In the ninth step, a display method is determined on the basis of the sensed illuminance information II. For example, the first display method is determined when the illuminance is greater than or equal to the predetermined value, whereas the second display method is determined when the illuminance is less than the predetermined value. Specifically, the first display method may be determined when the illuminance is greater than or equal to 1000 lux, and the second display method may be determined when the illuminance is less than 1000 lux (see S9 in FIG. 7B).

For example, the first-status control information SS is supplied when the first display method is used, the second-status control information SS is supplied when the second display method is used, and the third-status control information SS is supplied when the third display method is used.

### [Tenth Step]

In the tenth step, the interrupt processing terminates (see S10 in FIG. 7B).

### <Structure Example 2 of Information Processing Device>

In this embodiment, another structure of the information processing device of one embodiment of the present invention will be described with reference to FIG. 8.

FIG. 8 is a flow chart illustrating the program of one embodiment of the present invention. The interrupt processing in the flow chart in FIG. 8 is different from that in FIG. 7B.

Note that the structure example 2 of the information processing device is different from the interrupt processing in FIGS. 7A and 7B in that the interrupt processing includes a step for determining a display method on the basis of a display method which is manually set. Different structures will be described in detail below, and the above description is referred to for the other similar structures.

### <<Interrupt Processing>>

The interrupt processing includes sixth to thirteenth steps described below (see FIG. 8).

### [Sixth Step]

In the sixth step, a method for determining the display method is set. For example, a method for determining the display method manually or automatically can be set (see T6 in FIG. 8).

Specifically, the display method can be manually set to the first display method or the second display method. Alternatively, the first display method or the second display method can be automatically set on the basis of the sensed illuminance information II.

For example, the display method may be set by using predetermined event which is related with an order setting the display method.

### [Seventh Step]

In the seventh step, when the first display method is set to use, the first display method is determined as the display method and the processing proceeds to the thirteenth step. Furthermore, when the first display is not set to use, the processing proceeds to the eighth step (see T7 in FIG. 8).

Specifically, when the second display method is set to use or when the display method is determined on the basis of the sensed illuminance information II, the processing proceeds to the eighth step.

### [Eighth Step]

In the eighth step, the attitude of the information processing device is sensed (see T8 in FIG. 8). For example, an average value of the slopes of the housing 201 sensed during the predetermined period of time can be used as an index indicating the attitude. Specifically, the predetermined period of time may be longer than 0 seconds and shorter than 0.1 seconds, longer than or equal to 0.1 seconds and shorter than 0.5 seconds, longer than or equal to 0.5 seconds and shorter than 1 second, longer than or equal to 1 second and shorter than 5 seconds, or longer than or equal to 5 seconds.

### [Ninth Step]

In the ninth step, a region is selected on the basis of the sensed attitude (see T9 in FIG. 8). For example, a region on the top is selected.

### [Tenth Step]

In the tenth step, the illuminance of the selected region is sensed by driving the photosensor for measuring the illuminance of the region (see T10 in FIG. 8).

### [Eleventh Step]

In the eleventh step, when the second display method is set to use, the second display method is determined as the display method and the processing proceeds to the thirteenth step, whereas the processing proceeds to the twelfth step when the second display is not set to use (see T11 in FIG. 8).

Specifically, when the display method is automatically determined on the basis of the sensed illuminance information II, the processing proceeds to the twelfth step.

### [Twelfth Step]

In the twelfth step, the display method is determined on the basis of the sensed illuminance information II. For example, the first display method is determined when the illuminance is greater than or equal to the predetermined value, whereas the second display method is determined when the illuminance is less than the predetermined value. Specifically, the first display method is determined when the illuminance is greater than or equal to 1000 lux, and the second display method is determined when the illuminance is less than 1000 lux (see T12 in FIG. 8).

### [Thirteenth Step]

In the thirteenth step, the interrupt processing terminates (see T13 in FIG. 8).

### <<Predetermined Event>>

For example, the following events can be used: events supplied using a pointing device such as a mouse (e.g., “click” and “drag”) and events supplied to a touch panel with a finger or the like used as a pointer (e.g., “tap”, “drag”, or “swipe”).

Furthermore, for example, the position of a slide bar pointed by a pointer, the swipe speed, and the drag speed can be used as parameters assigned to an instruction associated with the predetermined event.

For example, information sensed by the sensor portion 250 is compared to the set threshold, and the compared results can be used for the event.

Specifically, a button that can be pushed in a housing, a pressure sensor in contact with the button or the like, or the like can be used as the sensor portion 250.

<<Instruction Associated with Predetermined Event>>

For example, the termination instruction can be associated with a predetermined event.

For example, “page-turning instruction” for switching displayed image information from one to another can be associated with a predetermined event. Note that a parameter for determining the page-turning speed or the like when the “page-turning instruction” is executed can be supplied using the predetermined event.

For example, “scroll instruction” for moving the display position of part of image information and displaying another part continuing from that part can be associated with a predetermined event. Note that a parameter for determining the moving speed of the display position or the like when the “scroll instruction” is executed can be supplied using the predetermined event.

For example, an instruction for generating image information can be associated with a predetermined event. Note that the ambient luminance sensed by the sensor portion 250 may be used for a parameter for determining the brightness of a generated image.

### <Structure Example 3 of Information Processing Device>

In this embodiment, another structure of the information processing device of one embodiment of the present invention will be described with reference to FIG. 9.

FIG. 9 is a flow chart illustrating the program of one embodiment of the present invention. The interrupt processing in the flow chart in FIG. 9 is different from that in FIG. 7B.

Note that a structure example 3 of the information processing device is different from the interrupt processing in FIG. 7B in that the interrupt processing includes a step in which a mode is changed on the basis of supplied predetermined event. Different structures will be described in detail below, and the above description is referred to for the other similar structures.

### <<Interrupt Processing>>

The interrupt processing includes sixth to eighth steps described below (see FIG. 9).

### <<Sixth Step>>

In the sixth step, the processing proceeds to the seventh step when a predetermined event has been supplied, whereas the processing proceeds to the eighth step when the predetermined event has not been supplied (see U6 in FIG. 9). For example, whether the predetermined event is supplied in a predetermined period or not can be a branch condition. Specifically, the predetermined period can be longer than 0 seconds and shorter than or equal to 5 seconds, preferably shorter than or equal to 1 second, further preferably shorter than or equal to 0.5 seconds, still further preferably shorter than or equal to 0.1 seconds.

### <<Seventh Step>>

In the seventh step, the mode is changed (see U7 in FIG. 9). Specifically, the mode is changed to the second mode when the first mode has been selected, or the mode is changed to the first mode when the second mode has been selected.

### <<Eighth Step>>

In the eighth step, the interrupt processing terminates (see U8 in FIG. 9). Note that in a period in which the main processing is executed, the interrupt processing may be repeatedly executed.

Note that this embodiment can be combined with any of the other embodiments in this specification as appropriate.

### Embodiment 2

In this embodiment, a structure of an input/output device that can be used for an information processing device of one embodiment of the present invention is described with reference to FIGS. 10A, 10B-1, 10B-2, and 10C, FIGS. 11A and 11B, FIGS. 12A and 12B, FIGS. 13A and 13B, FIGS. 14A to 14C, and FIG. 15.

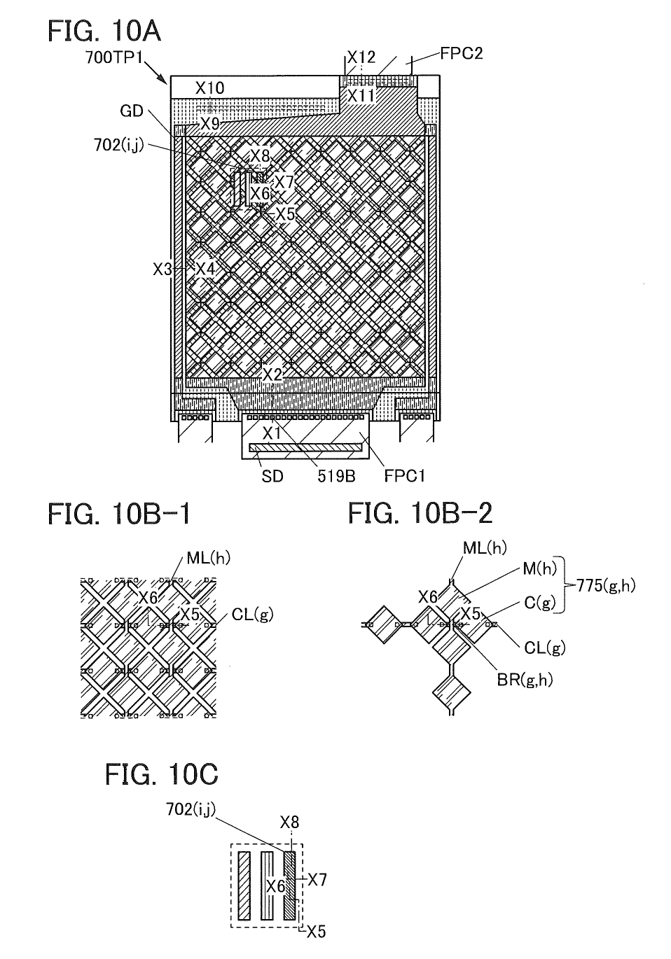

FIGS. 10A, 10B-1, 10B-2, and 10C illustrate a structure of a touch panel 700TP1 which can be used for an input/output device of one embodiment of the present invention. FIG. 10A is a top view of the touch panel. FIG. 10B-1 is a schematic view illustrating part of an input portion of the touch panel. FIG. 10B-2 is a schematic view illustrating part of the structure of FIG. 10B-1. FIG. 10C is a schematic view illustrating part of the display portion 230 included in the touch panel.

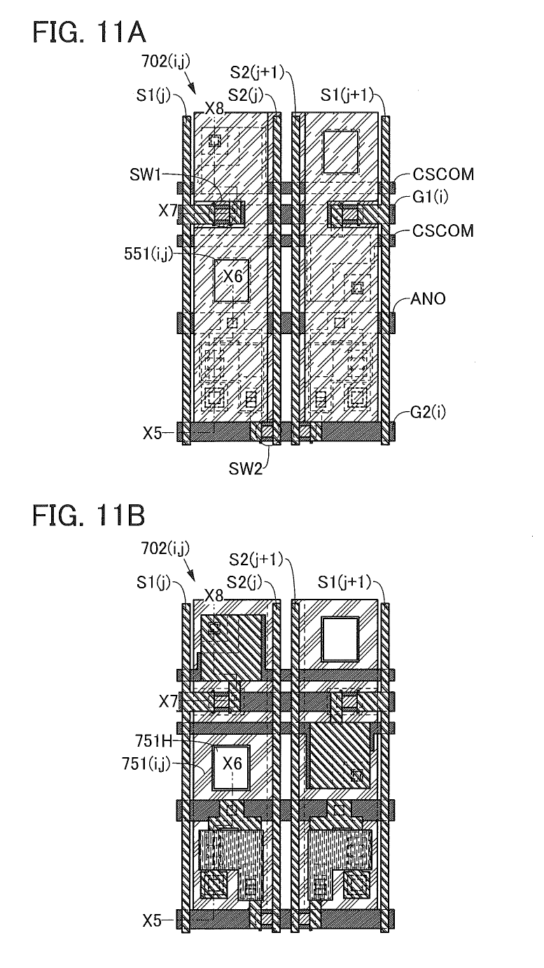

FIG. 11A is a bottom view illustrating part of the structure of the touch panel in FIG. 10C. FIG. 11B is a bottom view illustrating part of the structure in FIG. 11A in which some components are omitted.

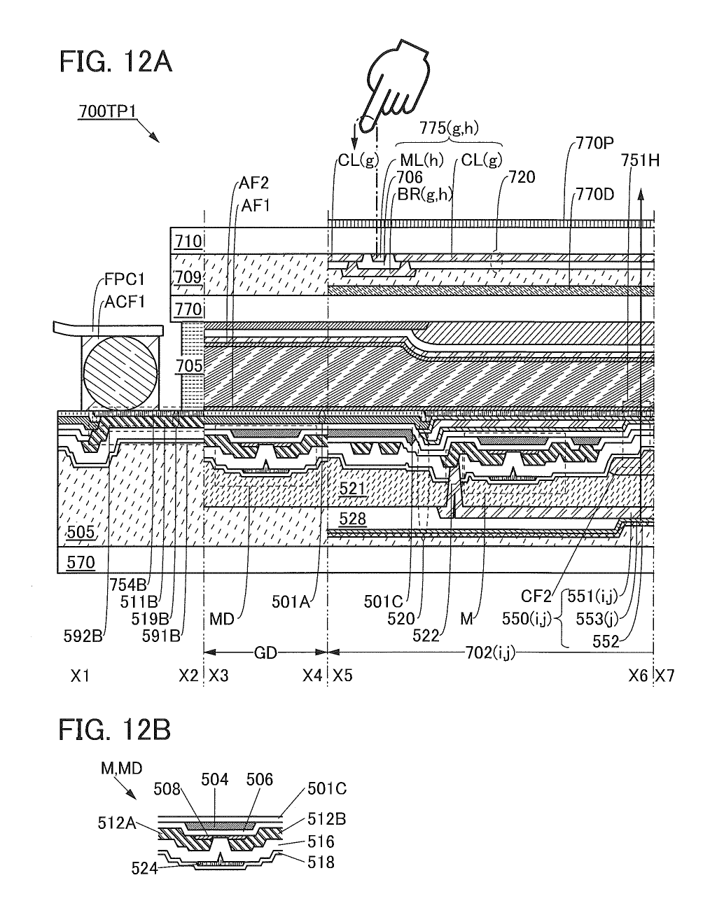

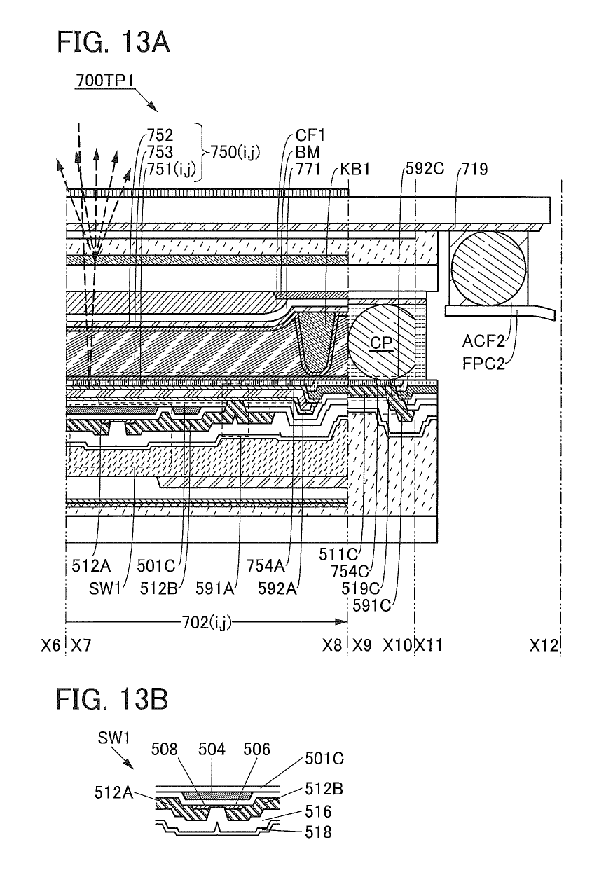

FIGS. 12A and 12B and FIGS. 13A and 13B are cross-sectional views illustrating the structure of the touch panel. FIG. 12A is a cross-sectional view taken along lines X1-X2, X3-X4, and X5-X6 in FIG. 10A, and FIG. 12B illustrates part of FIG. 12A.

FIG. 13A is a cross-sectional view taken along lines X7-X8, X9-X10, and X11-X12 in FIG. 10A, and FIG. 13B illustrates part of FIG. 13A.

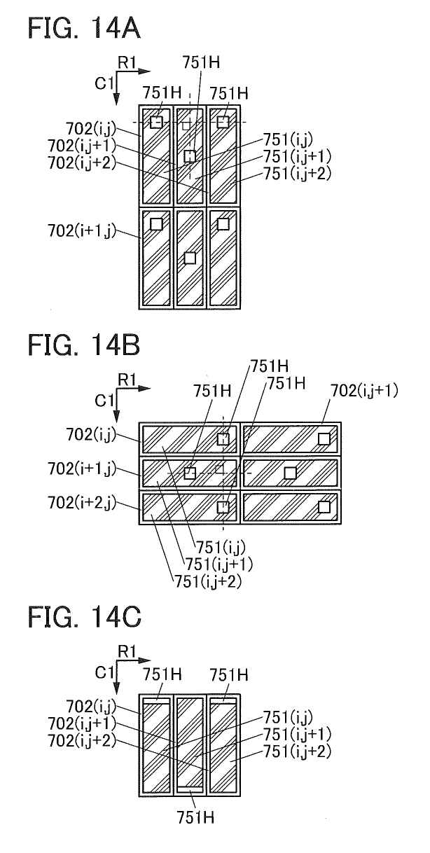

FIGS. 14A to 14C are schematic diagrams illustrating the shape of a reflective film which can be used for a pixel of the touch panel.

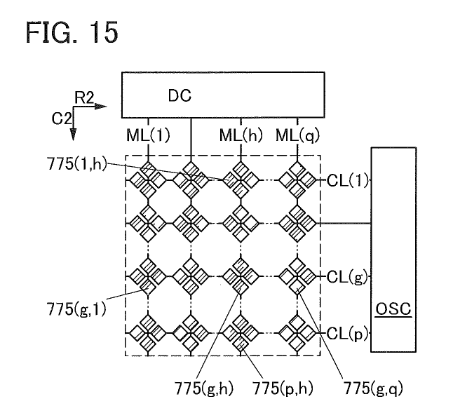

FIG. 15 is a block diagram illustrating the structure of the input portion of the touch panel.

### <Structure Example 1 of Input/Output Device>

The input/output device described in this embodiment includes the touch panel 700TP1 (see FIG. 10A). Note that the touch panel includes a display portion and an input portion.

### <<Structure Example of Display Portion>>

The display portion includes a display panel and the display panel includes a pixel 702(i, j).

### <<Pixel>>

The pixel 702(i, j) includes a second conductive film, a first conductive film, a second insulating film 501C, and the first display element 750(i, j) (see FIG. 13A).

The second conductive film is electrically connected to the pixel circuit 530(i, j). For example, a conductive film 512B which functions as a source electrode or a drain electrode of a transistor used as a switch SW1 of the pixel circuit 530(i, j) can be used as the second conductive film (see FIG. 13A and FIG. 6).

The first conductive film includes a region overlapping with the second conductive film. For example, the first conductive film can be used for a first electrode 751(i, j) of the first display element 750(i, j).

The second insulating film 501C includes a region sandwiched between the second conductive film and the first conductive film. The second insulating film 501C has an opening 591A in the region sandwiched between the first conductive film and the second conductive film. Furthermore, the second insulating film 501C includes a region sandwiched between a first insulating film 501A and a conductive film 511B. Moreover, the second insulating film 501C has an opening 591B in the region sandwiched between the first insulating film 501A and the conductive film 511B. The second insulating film 501C has an opening 591C in a region sandwiched between the first insulating film 501A and a conductive film 511C (see FIGS. 12A and 12B and FIGS. 13A and 13B).

The first conductive film is electrically connected to the second conductive film through the opening 591A. For example, the first electrode 751(i, j) is electrically connected to the conductive film 512B. The first conductive film electrically connected to the second conductive film through the opening 591A provided in the second insulating film 501C can be referred to as a penetration electrode.

The first display element 750(i, j) is electrically connected to the first conductive film.

The first display element 750(i, j) includes a reflective film and has a function of controlling the intensity of light reflected by the reflective film. For example, the first conductive film, the first electrode 751(i, j), or the like can be used as the reflective film of the first display element 750(i, j).

The second display element 550(i, j) has a function of emitting light toward the second insulating film 501C (see FIG. 12A).

The reflective film has a shape including a region that does not block light emitted from the second display element 550(i, j).

The reflective film included in the pixel 702(i, j) of the display panel described in this embodiment includes one or a plurality of openings 751H (see FIGS. 14A to 14C).

The second display element 550(i, j) has a function of emitting light toward the opening 751H. Note that the first opening 751H transmits light emitted from the second display element 550(i, j).

The opening 751H of the pixel 702(i, j+1), which is adjacent to the pixel 702(i, j), is not provided on a line that extends in the row direction (the direction indicated by the arrow R1 in the drawing) through the opening 751H of the pixel 702(i, j) (see FIG. 14A). Alternatively, for example, the opening 751H of the pixel 702(i+1, j), which is adjacent to the pixel 702(i, j), is not provided on a line that extends in the column direction (the direction indicated by the arrow C1 in the drawing) through the opening 751H of the pixel 702(i, j) (see FIG. 14B).

For example, the opening 751H of the pixel 702(i, j+2) is provided on a line that extends in the row direction through the opening 751H of the pixel 702(i, j) (see FIG. 14A). In addition, the opening 751H of the pixel 702(i, j+1) is provided on a line that is perpendicular to the above-mentioned line between the opening 751H of the pixel 702(i, j) and the opening 751H of the pixel 702(i, j+2).

Alternatively, for example, the opening 751H of the pixel 702(i+2, j) is provided on a line that extends in the column direction through the opening 751H of the pixel 702(i, j) (see FIG. 14B). In addition, for example, the opening 751H of the pixel 702(i+1, j) is provided on a line that is perpendicular to the above-mentioned line between the opening 751H of the pixel 702(i, j) and the opening 751H of the pixel 702(i+2, j).

Thus, the third display element that displays a color different from that displayed by the second display element can be provided easily near the second display element. Thus, a novel display panel that is highly convenient or reliable can be provided.

For example, the reflective film can be formed using a material having a shape in which an end portion is cut off so as to form a region 751E that does not block light emitted from the second display element 550(i, j) (see FIG. 14C). Specifically, the first electrode 751(i, j) whose end portion is cut off so as to be shorter in the column direction (the direction indicated by the arrow C1 in the drawing) can be used as the reflective film.

Thus, the first display element and the second display element that displays an image using a method different from that of the first display element can be driven using a pixel circuit that can be formed in the same process. Specifically, a reflective display element is used as the first display element, whereby the power consumption can be reduced. In addition, an image with high contrast can be favorably displayed in an environment with bright external light. In addition, the second display element which emits light is used, whereby an image can be favorably displayed in a dark environment. Furthermore, using the second insulating film, impurity diffusion between the first display element and the second display element or between the first display element and the pixel circuit can be suppressed. Moreover, part of light emitted from the second display element to which a voltage controlled on the basis of the control information is supplied is not blocked by the reflective film included in the first display element. Consequently, a novel display device that is highly convenient or reliable can be provided.

The second display element 550(i, j) included in the pixel of the input/output device described in this embodiment is provided so that the display using the second display element 550(i, j) can be seen from part of a region from which the display using the first display element 750(i, j) can be seen. For example, dashed arrows shown in FIG. 13A denote the directions in which external light is incident on and reflected by the first display element 750(i, j) that performs display by controlling the intensity of external light reflection. In addition, a solid arrow shown in FIG. 12A denotes the direction in which the second display element 550(i, j) emits light to the part of the region from which the display using the first display element 750(i, j) can be seen.

Thus, the display using the second display element can be seen from part of the region from which the display using the first display element can be seen. Alternatively, a user can view the display without changing the attitude or the like of the display panel. Thus, a novel display panel that is highly convenient or reliable can be provided.

The pixel circuit 530(i, j) is electrically connected to the signal line S1(j). Note that a conductive film 512A is electrically connected to the signal line S1(j) (see FIG. 13A and FIG. 6). Furthermore, for example, the transistor in which the second conductive film is used as the conductive film 512B serving as a source electrode or a drain electrode can be used as the switch SW1 of the pixel circuit 530(i, j).

The display panel described in this embodiment includes the first insulating film 501A (see FIG. 12A).

The first insulating film 501A has a first opening 592A, a second opening 592B, and an opening 592C (see FIG. 12A and FIG. 13A).

The first opening 592A includes a region overlapping with a first intermediate film 754A and the first electrode 751(i, j) or a region overlapping with the first intermediate film 754A and the second insulating film 501C.

The second opening 592B includes a region overlapping with a second intermediate film 754B and the conductive film 511B. Furthermore, the opening 592C includes a region overlapping with an intermediate film 754C and the conductive film 511C.

The first insulating film 501A includes a region sandwiched between the first intermediate film 754A and the second insulating film 501C along the periphery of the first opening 592A, and the first insulating film 501A includes a region sandwiched between the second intermediate film 754B and the conductive film 511B along the periphery of the second opening 592B.

The display panel described in this embodiment includes a scan line G2(i), a wiring CSCOM, a third conductive film ANO, and a signal line S2(j) (see FIG. 6).

The second display element 550(i, j) of the display panel described in this embodiment includes a third electrode 551(i, j), a fourth electrode 552, and a layer 553(j) containing a light-emitting material (see FIG. 12A). Note that the third electrode 551(i, j) and the fourth electrode 552 are electrically connected to the third conductive film ANO and the fourth conductive film VCOM2, respectively (see FIG. 6).

The fourth electrode 552 includes a region overlapping with the third electrode 551(i, j).

The layer 553(j) containing a light-emitting material includes a region sandwiched between the third electrode 551(i, j) and the fourth electrode 552.

The third electrode 551(i, j) is electrically connected to the pixel circuit 530(i, j) at a connection portion 522.

The first display element 750(i, j) of the display panel described in this embodiment includes a layer 753 containing a liquid crystal material, the first electrode 751(i, j), and a second electrode 752. The second electrode 752 is positioned such that an electric field which controls the alignment of the liquid crystal material is generated between the second electrode 752 and the first electrode 751(i, j) (see FIG. 12A and FIG. 13A).

The display panel described in this embodiment includes an alignment film AF1 and an alignment film AF2. The alignment film AF2 is provided such that the layer 753 containing a liquid crystal material is interposed between the alignment film AF1 and the alignment film AF2.

The display panel described in this embodiment includes the first intermediate film 754A and the second intermediate film 754B.

The first intermediate film 754A includes a region which overlaps with the second insulating film 501C with the first conductive film interposed therebetween, and the first intermediate film 754A includes a region in contact with the first electrode 751(i, j). The second intermediate film 754B includes a region in contact with the conductive film 511B.

The display panel described in this embodiment includes a light-blocking film BM, an insulating film 771, a functional film 770P, and a functional film 770D. In addition, a coloring film CF1 and a coloring film CF2 are included.

The light-blocking film BM has an opening in a region overlapping with the first display element 750(i, j). The coloring film CF2 is provided between the second insulating film 501C and the second display element 550(i, j) and includes a region overlapping with the opening 751H (see FIG. 12A).

The insulating film 771 includes a region sandwiched between the coloring film CF1 and the layer 753 containing a liquid crystal material or between the light-blocking film BM and the layer 753 containing a liquid crystal material. Thus, unevenness due to the thickness of the coloring film CF1 can be avoided. Alternatively, impurities can be prevented from being diffused from the light blocking film BM, the coloring film CF1, or the like to the layer 753 containing a liquid crystal material

The functional film 770P includes a region overlapping with the first display element 750(i, j).

The functional film 770D includes a region overlapping with the first display element 750(i, j). The functional film 770D is provided so that a substrate 770 lies between the functional film 770D and the first display element 750(i, j). This can diffuse light reflected by the first display element 750(i, j), for example.

The display panel described in this embodiment includes a substrate 570, the substrate 770, and a functional layer 520.

The substrate 770 includes a region overlapping with the substrate 570.

The functional layer 520 includes a region sandwiched between the substrate 570 and the substrate 770. The functional layer 520 includes the pixel circuit 530(i, j), the second display element 550(i, j), an insulating film 521, and an insulating film 528. The functional layer 520 includes an insulating film 518 and an insulating film 516 (see FIGS. 12A and 12B).

The insulating film 521 includes a region sandwiched between the pixel circuit 530(i, j) and the second display element 550(i, j).

The insulating film 528 is provided between the insulating film 521 and the substrate 570 and has an opening in a region overlapping with the second display element 550(i, j).

The insulating film 528 formed along the periphery of the third electrode 551(i, j) can prevent a short circuit between the third electrode 551(i, j) and the fourth electrode.

The insulating film 518 includes a region sandwiched between the insulating film 521 and the pixel circuit 530(i, j). The insulating film 516 includes a region sandwiched between the insulating film 518 and the pixel circuit 530(i, j).

The display panel described in this embodiment also includes a bonding layer 505, a sealing material 705, and a structure body KB1.

The bonding layer 505 includes a region sandwiched between the functional layer 520 and the substrate 570, and has a function of bonding the functional layer 520 and the substrate 570 together.

The sealing material 705 includes a region sandwiched between the functional layer 520 and the substrate 770, and has a function of bonding the functional layer 520 and the substrate 770 together.

The structure body KB1 has a function of providing a certain space between the functional layer 520 and the substrate 770.

The display panel described in this embodiment includes a terminal 519B and a terminal 519C.

The terminal 519B includes the conductive film 511B and the intermediate film 754B, and the intermediate film 754B includes a region in contact with the conductive film 511B. The terminal 519B is electrically connected to the signal line S1(j), for example.

The terminal 519C includes the conductive film 511C and the intermediate film 754C, and the intermediate film 754C includes a region in contact with the conductive film 511C. The conductive film 511C is electrically connected to the wiring VCOM1, for example.

A conductive material CP is sandwiched between the terminal 519C and the second electrode 752, and has a function of electrically connecting the terminal 519C and the second electrode 752. For example, a conductive particle can be used as the conductive material CP.

Moreover, the display panel described in this embodiment includes a driver circuit GD and a driver circuit SD (see FIG. 4 and FIGS. 10A, 10B-1, 10B-2, and 10C).

The driver circuit GD is electrically connected to the scan line G1(i). The driver circuit GD includes a transistor MD, for example (see FIG. 12A). Specifically, a transistor including a semiconductor film that can be formed in the same process as the transistor included in the pixel circuit 530(i, j) can be used as the transistor MD.

The driver circuit SD is electrically connected to the signal line S1(j). The driver circuit SD is electrically connected to the terminal 519B, for example.

### <<Structure Example of Input Portion>>

An input portion includes a region overlapping with the display panel (see FIGS. 10A, 10B-1, 10B-2, and 10C, FIG. 12A, or FIG. 13A).

The input portion includes a control line CL(g), a sensor signal line ML(h), and a sensing element 775(g, h) (see FIG. 10B-2).

The sensing element 775(g, h) is electrically connected to the control line CL(g) and the sensor signal line ML(h).

Note that the control line CL(g) has a function of supplying a control signal.

The sensing element 775(g, h) has a function of receiving the control signal and a function of supplying the control signal and a sensor signal which changes in accordance with a distance between the sensing element 775(g, h) and an object approaching a region overlapping with a display panel.

The sensor signal line ML(h) has a function of receiving the sensor signal.

The sensing element 775(g, h) has a light-transmitting property.

The sensing element 775(g, h) includes an electrode C(g) and an electrode M(h).

The electrode C(g) is electrically connected to the control line CL(g).

The electrode M(h) is electrically connected to the sensor signal line ML(h) and is positioned so that an electric field part of which is blocked by an object approaching a region overlapping with a display panel is generated between the electrode M(h) and the electrode C(g).

Thus, the object approaching the region overlapping with the display panel can be sensed while the image information is displayed on the display panel.

The input portion described in this embodiment includes a substrate 710 and a bonding layer 709 (see FIG. 12A and FIG. 13A).

The substrate 710 is provided so that the sensing element 775(g, h) is sandwiched between the substrate 710 and the substrate 770.

The bonding layer 709 is provided between the substrate 770 and the sensing element 775(g, h) and has a function of bonding the substrate 770 with the sensing element 775(g, h) together.

The functional film 770P is provided so that the sensing element 775(g, h) is sandwiched between the functional film 770P and the first display element 750(i, j).

Thus, the intensity of light reflected by the sensing element 775(g, h) can be reduced, for example.

The input portion described in this embodiment includes one group of sensing elements 775(g, 1) to 775(g, q) and another group of sensing elements 775(1, h) to 775(p, h) (see FIG. 15). Note that g is an integer greater than or equal to 1 and less than or equal to p, h is an integer greater than or equal to 1 and less than or equal to q, and p and q are each an integer greater than or equal to 1.

The one group of the sensing elements 775(g, 1) to 775(g, q) include the sensing element 775(g, h). The sensing elements 775(g, 1) to 775(g, q) are arranged in a row direction (indicated by the arrow R2 in the drawing). Note that the direction indicated by the arrow R2 in FIG. 15 may be the same as or different from the direction indicated by the arrow R1 in FIG. 4.

The another group of sensing elements 775(1, h) to 775(p, h) include the sensing element 775(g, h) and are provided in the column direction (the direction indicated by the arrow C2 in the drawing) that intersects the row direction.

The one group of sensing elements 775(g, 1) to 775(g, q) provided in the row direction include the electrode C(g) that is electrically connected to the control line CL(g).

The another group of sensing elements 775(1, h) to 775(p, h) provided in the column direction include the electrode M(h) that is electrically connected to the sensor signal line ML(h).

The control line CL(g) of the touch panel described in this embodiment includes a conductive film BR(g, h) (see FIG. 12A). The conductive film BR(g, h) includes a region overlapping with the sensor signal line ML(h).

An insulating film 706 includes a region sandwiched between the sensor signal line ML(h) and the conductive film BR(g, h). Thus, a short circuit between the sensor signal line ML(h) and the conductive film BR(g, h) can be prevented.

The touch panel described in this embodiment includes an oscillator circuit OSC and a detection circuit DC (see FIG. 15).

The oscillator circuit OSC is electrically connected to the control line CL(g) and has a function of supplying a control signal. For example, a rectangular wave, a sawtooth wave, a triangular wave, or the like can be used as the control signal.

The detection circuit DC is electrically connected to the sensor signal line ML(h) and has a function of supplying a sensor signal on the basis of a change in the potential of the sensor signal line ML(h).

Individual components included in the touch panel are described below. Note that these components cannot be clearly distinguished and one component may also serve as another component or include part of another component.

For example, the first conductive film can be used as the first electrode 751(i, j). The first conductive film can be used as a reflective film.

In addition, the second conductive film can be used as the conductive film 512B serving as a source electrode or a drain electrode of the transistor.

### Structure Example

The display panel of one embodiment of the present invention includes the substrate 570, the substrate 770, the structure body KB1, the sealing material 705, or the bonding layer 505.

In addition, the display panel of one embodiment of the present invention includes the functional layer 520, the insulating film 521, or the insulating film 528.

The display panel of one embodiment of the present invention also includes the signal line S1(j), the signal line S2(j), the scan line G1(i), the scan line G2(i), the wiring CSCOM, or the third conductive film ANO.

The display panel of one embodiment of the present invention also includes the first conductive film or the second conductive film.

The display panel of one embodiment of the present invention also includes the terminal 519B, the terminal 519C, the conductive film 511B, or the conductive film 511C.

The display panel of one embodiment of the present invention also includes the pixel circuit 530(i, j) or the switch SW1.

The display panel of one embodiment of the present invention also includes the first display element 750(i, j), the first electrode 751(i, j), the reflective film, the opening, the layer 753 containing a liquid crystal material, or the second electrode 752.

In addition, the display panel of one embodiment of the present invention includes the alignment film AF1, the alignment film AF2, the coloring film CF1, the coloring film CF2, the light-blocking film BM, the insulating film 771, the functional film 770P, or the functional film 770D.

In addition, the display panel of one embodiment of the present invention includes the second display element 550(i, j), the third electrode 551(i, j), the fourth electrode 552, or the layer 553(j) containing a light-emitting material.

The display panel of one embodiment of the present invention also includes the first insulating film 501A and the second insulating film 501C.

The display panel of one embodiment of the present invention also includes the driver circuit GD or the driver circuit SD.

The input portion includes the substrate 710, a functional layer 720, the bonding layer 709, and a terminal 719 (see FIG. 12A and FIG. 13A).

The functional layer 720 includes a region sandwiched between the substrate 770 and the substrate 710. The functional layer 720 includes the sensing element 775(g, h) and the insulating film 706.

The bonding layer 709 is provided between the functional layer 720 and the substrate 770, and has a function of bonding the functional layer 720 to the substrate 770 together.

The terminal 719 is electrically connected to the sensing element 775(g, h).

### <<Substrate 570>>

The substrate 570 or the like can be formed using a material having heat resistance high enough to withstand heat treatment in the manufacturing process. For example, a material with a thickness of less than or equal to 0.7 mm and more than or equal to 0.1 mm can be used as the substrate 570. Specifically, a material polished to a thickness of approximately 0.1 mm can be used.

For example, a large-sized glass substrate having any of the following sizes can be used as the substrate 570 or the like: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

For the substrate 570 or the like, an organic material, an inorganic material, a composite material of an organic material and an inorganic material, or the like can be used. For example, an inorganic material such as glass, ceramic, or metal can be used for the substrate 570 or the like.

Specifically, non-alkali glass, soda-lime glass, potash glass, crystal glass, aluminosilicate glass, tempered glass, chemically tempered glass, quartz, sapphire, or the like can be used for the substrate 570 or the like. Specifically, an inorganic oxide film, an inorganic nitride film, an inorganic oxynitride film, or the like can be used for the substrate 570 or the like. For example, a silicon oxide film, a silicon nitride film, a silicon oxynitride film, an aluminum oxide film, or the like can be used for the substrate 570 or the like. Stainless steel, aluminum, or the like can be used for the substrate 570 or the like.

For example, a single crystal semiconductor substrate or a polycrystalline semiconductor substrate of silicon or silicon carbide, a compound semiconductor substrate of silicon germanium or the like, an SOI substrate, or the like can be used as the substrate 570 or the like. Thus, a semiconductor element can be provided over the substrate 570 or the like.

For example, an organic material such as a resin, a resin film, or plastic can be used for the substrate 570 or the like. Specifically, a resin film or a resin plate of polyester, polyolefin, polyamide, polyimide, polycarbonate, an acrylic resin, or the like can be used for the substrate 570 or the like.

For example, a composite material formed by attaching a metal plate, a thin glass plate, or a film of an inorganic material to a resin film or the like can be used for the substrate 570 or the like. For example, a composite material formed by dispersing a fibrous or particulate metal, glass, an inorganic material, or the like into a resin film can be used for the substrate 570 or the like. For example, a composite material formed by dispersing a fibrous or particulate resin, an organic material, or the like into an inorganic material can be used for the substrate 570 or the like.

Furthermore, a single-layer material or a layered material in which a plurality of layers are stacked can be used for the substrate 570 or the like. For example, a layered material in which a base, an insulating film that prevents diffusion of impurities contained in the base, and the like are stacked can be used for the substrate 570 or the like. Specifically, a layered material in which glass and one or a plurality of films that are selected from a silicon oxide layer, a silicon nitride layer, a silicon oxynitride layer, and the like and that prevent diffusion of impurities contained in the glass are stacked can be used for the substrate 570 or the like. Alternatively, a layered material in which a resin and a film for preventing diffusion of impurities that penetrate the resin, such as a silicon oxide film, a silicon nitride film, or a silicon oxynitride film, are stacked can be used for the substrate 570 or the like.

Specifically, a resin film, a resin plate, a layered material, or the like of polyester, polyolefin, polyamide, polyimide, polycarbonate, an acrylic resin, or the like can be used for the substrate 570 or the like.

Specifically, a material including polyester, polyolefin, polyamide (e.g., nylon or aramid), polyimide, polycarbonate, polyurethane, an acrylic resin, an epoxy resin, or a resin having a siloxane bond, such as silicone, can be used for the substrate 570 or the like.

Specifically, polyethylene terephthalate (PET), polyethylene naphthalate (PEN), polyethersulfone (PES), an acrylic resin, or the like can be used for the substrate 570 or the like.

Alternatively, paper, wood, or the like can be used for the substrate 570 or the like.

For example, a flexible substrate can be used as the substrate 570 or the like.

Note that a transistor, a capacitor, or the like can be directly formed on the substrate. Alternatively, a transistor, a capacitor, or the like can be formed on a substrate which is for use in the manufacturing process and can withstand heat applied in the manufacturing process, and then the transistor, the capacitor, or the like can be transferred to the substrate 570 or the like. Thus, a transistor, a capacitor, or the like can be formed over a flexible substrate, for example.

### <<Substrate 770>>

For example, a light-transmitting material can be used for the substrate 770. Specifically, any of the materials that can be used for the substrate 570 can be used for the substrate 770.

For example, aluminosilicate glass, tempered glass, chemically tempered glass, sapphire, or the like can be favorably used for the substrate 770 that is provided on the user side of the display panel. This can prevent damage or a crack of the display panel caused by the use thereof.

Moreover, a material having a thickness of more than or equal to 0.1 mm and less than or equal to 0.7 mm, for example, can be used for the substrate 770. Specifically, a substrate polished for reducing the thickness can be used. Thus, the functional film 770D can be provided near the first display element 750(i, j), which makes it possible to reduce an image blur and to display a clear image.

### <<Structure Body KB1>>

The structure body KB1 or the like can be formed using an organic material, an inorganic material, or a composite material of an organic material and an inorganic material. Accordingly, a predetermined space can be provided between components between which the structure KB1 and the like are provided.

Specifically, for the structure body KB1, polyester, polyolefin, polyamide, polyimide, polycarbonate, polysiloxane, an acrylic resin, or the like, or a composite material of a plurality of resins selected from these can be used. Alternatively, a photosensitive material may be used.

### <<Sealing Material 705>>

For the sealing material 705 or the like, an inorganic material, an organic material, a composite material of an inorganic material and an organic material, or the like can be used.

For example, an organic material such as a thermally fusible resin or a curable resin can be used for the sealing material 705 or the like.

For example, an organic material such as a reactive curable adhesive, a light curable adhesive, a thermosetting adhesive, and/or an anaerobic adhesive can be used for the sealing material 705 or the like.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, or the like can be used for the sealing material 705 or the like.

### <<Bonding Layer 505>>

For example, any of the materials that can be used for the sealing material 705 can be used for the bonding layer 505.

### <<Insulating Film 521>>

For example, an insulating inorganic material, an insulating organic material, or an insulating composite material containing an inorganic material and an organic material can be used for the insulating film 521 or the like.

Specifically, an inorganic oxide film, an inorganic nitride film, an inorganic oxynitride film, or a layered material obtained by stacking some of these films can be used as the insulating film 521 or the like. For example, a film including any of a silicon oxide film, a silicon nitride film, a silicon oxynitride film, an aluminum oxide film, and the like, or a film including a material obtained by stacking some of these films can be used as the insulating film 521 or the like.

Specifically, for the insulating film 521 or the like, polyester, polyolefin, polyamide, polyimide, polycarbonate, polysiloxane, an acrylic resin, or the like, or a layered or composite material of a plurality of kinds of resins selected from these can be used. Alternatively, a photosensitive material may be used.

Thus, steps due to various components overlapping with the insulating film 521, for example, can be reduced.

### <<Insulating Film 528>>

For example, any of the materials that can be used for the insulating film 521 can be used for the insulating film 528 or the like. Specifically, a 1-μm-thick polyimide-containing film can be used as the insulating film 528.

### <<First Insulating Film 501A>>

For example, any of the materials that can be used for the insulating film 521 can be used for the first insulating film 501A. For example, a material having a function of supplying hydrogen can be used for the first insulating film 501A.

Specifically, a material obtained by stacking a material containing silicon and oxygen and a material containing silicon and nitrogen can be used for the first insulating film 501A. For example, a material having a function of releasing hydrogen by heating or the like to supply the hydrogen to another component can be used for the first insulating film 501A. Specifically, a material having a function of releasing hydrogen taken in the manufacturing process, by heating or the like, to supply the hydrogen to another component can be used for the first insulating film 501A.

For example, a film containing silicon and oxygen that is formed by a chemical vapor deposition method using silane or the like as a source gas can be used as the first insulating film 501A.

Specifically, a material obtained by stacking a material containing silicon and oxygen and having a thickness of more than or equal to 200 nm and less than or equal to 600 nm and a material containing silicon and nitrogen and having a thickness of approximately 200 nm can be used for the first insulating film 501A.

### <<Second Insulating Film 501C>>

For example, any of the materials that can be used for the insulating film 521 can be used for the second insulating film 501C. Specifically, a material containing silicon and oxygen can be used for the second insulating film 501C. Thus, diffusion of impurities into the pixel circuit, the second display element, or the like can be suppressed.

For example, a 200-nm-thick film containing silicon, oxygen, and nitrogen can be used as the second insulating film 501C.

### <<Intermediate Film 754A, Intermediate Film 754B, Intermediate Film 754C>>

For example, a film with a thickness greater than or equal to 10 nm and less than or equal to 500 nm, preferably greater than or equal to 10 nm and less than or equal to 100 nm can be used as the intermediate film 754A, the intermediate film 754B, or the intermediate film 754C. In this specification, the intermediate film 754A, the intermediate film 754B, or the intermediate film 754C is referred to as an intermediate film.

For example, a material having a function of allowing the passage of hydrogen or the supply of hydrogen can be used for the intermediate film.

For example, a conductive material can be used for the intermediate film.

For example, a light-transmitting material can be used for the intermediate film.

Specifically, a material containing indium and oxygen, a material containing indium, gallium, zinc, and oxygen, a material containing indium, tin, and oxygen, or the like can be used for the intermediate film. Note that these materials have a function of allowing the passage of hydrogen.

Specifically, a 50- or 100-nm-thick film containing indium, gallium, zinc, and oxygen can be used as the intermediate film.

Note that a material obtained by stacking films serving as an etching stopper can be used as the intermediate film. Specifically, a layered material obtained by stacking a 50-nm-thick film containing indium, gallium, zinc, and oxygen and a 20-nm-thick film containing indium, tin, and oxygen, in this order, can be used for the intermediate film.

### <<Wiring, Terminal, Conductive Film>>

A conductive material can be used for the wiring or the like. Specifically, the conductive material can be used for the signal line S1(j), the signal line S2(j), the scan line G1(i), the scan line G2(i), the wiring CSCOM, the third conductive film ANO, the terminal 519B, the terminal 519C, a terminal 719, the conductive film 511B, the conductive film 511C, or the like.

For example, an inorganic conductive material, an organic conductive material, a metal, conductive ceramics, or the like can be used for the wiring or the like.

Specifically, a metal element selected from aluminum, gold, platinum, silver, copper, chromium, tantalum, titanium, molybdenum, tungsten, nickel, iron, cobalt, palladium, and manganese can be used for the wiring or the like. Alternatively, an alloy including any of the above-described metal elements, or the like can be used for the wiring or the like. In particular, an alloy of copper and manganese is suitably used in microfabrication with the use of a wet etching method.

Specifically, any of the following structures can be used for the wiring or the like: a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like.

Specifically, a conductive oxide, such as indium oxide, indium tin oxide, indium zinc oxide, zinc oxide, or zinc oxide to which gallium is added, can be used for the wiring or the like.

Specifically, a film containing graphene or graphite can be used for the wiring or the like.

For example, a film including graphene oxide is formed and is subjected to reduction, so that a film including graphene can be formed. As a reducing method, a method with application of heat, a method using a reducing agent, or the like can be employed.

For example, a film including a metal nanowire can be used for the wiring or the like. Specifically, a nanowire including silver can be used.

Specifically, a conductive high molecule can be used for the wiring or the like.

Note that the terminal 519B can be electrically connected to a flexible printed circuit FPC1 using a conductive material ACF1, for example.

### <<First Conductive Film, Second Conductive Film>>

For example, any of the materials that can be used for the wiring or the like can be used for the first conductive film or the second conductive film.

Alternatively, the first electrode 751(i, j), the wiring, or the like can be used for the first conductive film.

For example, the conductive film 512B serving as a source electrode or a drain electrode of a transistor that can be used as the switch SW1, or the wiring or the like can be used for the second conductive film.

<<Pixel Circuit 530(i, j)>>

The pixel circuit 530(i, j) is electrically connected to the signal line S1(j), the signal line S2(j), the scan line G1(i), the scan line G2(i), the wiring CSCOM, and the third conductive film ANO (see FIG. 6).

The pixel circuit 530(i, j) includes the switch SW1 and a capacitor C11.

The pixel circuit 530(i, j) includes a switch SW2, a transistor M, and a capacitor C12.

For example, a transistor including a gate electrode electrically connected to the scan line G1(i) and a first electrode electrically connected to the signal line S1(j) can be used as the switch SW1.

The capacitor C11 includes a first electrode electrically connected to a second electrode of the transistor used as the switch SW1 and a second electrode electrically connected to the wiring CSCOM.

For example, a transistor including a gate electrode electrically connected to the scan line G2(i) and a first electrode electrically connected to the signal line S2(j) can be used as the switch SW2.

The transistor M includes a gate electrode electrically connected to the second electrode of the transistor used as the switch SW2 and includes a first electrode electrically connected to the third conductive film ANO.

Note that a transistor including a conductive film provided such that a semiconductor film is sandwiched between a gate electrode and the conductive film can be used as the transistor M. For example, as the conductive film, a conductive film electrically connected to a wiring that can supply the same potential as that of the gate electrode of the transistor M can be used.

The capacitor C12 includes a first electrode electrically connected to a second electrode of the transistor used as the switch SW2 and a second electrode electrically connected to the first electrode of the transistor M.

The first electrode and the second electrode of the first display element 750(i, j) are electrically connected to the second electrode of the transistor used as the switch SW1 and the wiring VCOM1, respectively. This enables the first display element 750 to be driven.

Furthermore, the first electrode and the second electrode of the second display element 550(i, j) are electrically connected to the second electrode of the transistor M and the fourth conductive film VCOM2, respectively. This enables the second display element 550(i, j) to be driven.

### <<Switch SW1, Switch SW2, Transistor M, Transistor MD>>

For example, a bottom-gate or top-gate transistor or the like can be used as the switch SW1, the switch SW2, the transistor MD, or the like.

For example, a transistor including a semiconductor containing an element belonging to Group 14 in a semiconductor film can be used. Specifically, a semiconductor containing silicon can be used for a semiconductor film. For example, a transistor including single crystal silicon, polysilicon, microcrystalline silicon, amorphous silicon, or the like in a semiconductor film can be used.

For example, a transistor including an oxide semiconductor in a semiconductor film can be used. Specifically, an oxide semiconductor containing indium or an oxide semiconductor containing indium, gallium, and zinc can be used for a semiconductor film.

For example, a transistor whose leakage current in an off state is smaller than that of a transistor including amorphous silicon in a semiconductor film can be used as the switch SW1, the switch SW2, the transistor M, the transistor MD, or the like. Specifically, a transistor including an oxide semiconductor in a semiconductor film 508 can be used as the switch SW1, the switch SW2, the transistor M, the transistor MD, or the like.

Thus, a pixel circuit can hold an image signal for a longer time than a pixel circuit including a transistor that uses amorphous silicon for a semiconductor film. Specifically, a selection signal can be supplied at a frequency of lower than 30 Hz, preferably lower than 1 Hz, further preferably less than once per minute while flickering is suppressed. Consequently, eyestrain on a user of the information processing device can be reduced, and power consumption for driving can be reduced.

The transistor that can be used as the switch SW1 includes the semiconductor film 508 and a conductive film 504 including a region overlapping with the semiconductor film 508 (see FIG. 13B). The transistor that can be used as the switch SW1 includes the conductive film 512A and the conductive film 512B, which are electrically connected to the semiconductor film 508.

Note that the conductive film 504 and the insulating film 506 serve as a gate electrode and a gate insulating film, respectively. The conductive film 512A has one of a function of a source electrode and a function of a drain electrode, and the conductive an 512B has the other.

A transistor including a conductive film 524 provided such that the semiconductor film 508 is sandwiched between the conductive film 504 and the conductive film 524 can be used as the transistor M (see FIG. 12B).

A conductive film in which a 10-nm-thick film containing tantalum and nitrogen and a 300-nm-thick film containing copper are stacked in this order can be used as the conductive film 504, for example.

A material in which a 400-nm-thick film containing silicon and nitrogen and a 200-nm-thick film containing silicon, oxygen, and nitrogen are stacked can be used for the insulating film 506, for example.

A 25-nm-thick film containing indium, gallium, and zinc can be used as the semiconductor film 508, for example.

A conductive film in which a 50-nm-thick film containing tungsten, a 400-nm-thick film containing aluminum, and a 100-nm-thick film containing titanium are stacked in this order can be used as the conductive film 512A or the conductive film 512B, for example.

<<First Display Element 750(i, j)>>

For example, a display element having a function of controlling transmission or reflection of light can be used as the first display element 750(i, j) or the like. For example, a combined structure of a polarizing plate and a liquid crystal element or a MEMS shutter display element can be used. Specifically, a reflective liquid crystal display element can be used as the first display element 750(i, j). The use of a reflective display element leads to a reduction of power consumption of a display panel.

For example, a liquid crystal element that can be driven by any of the following driving methods can be used: an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, and the like.

In addition, a liquid crystal element that can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

The first display element 750(i, j) includes a first electrode, a second electrode, and a liquid crystal layer. The liquid crystal layer contains a liquid crystal material whose orientation is controlled by a voltage applied between the first electrode and the second electrode. For example, the orientation of the liquid crystal material can be controlled by an electric field in the thickness direction (also referred to as the vertical direction), the direction that crosses the vertical direction (the horizontal direction, or the diagonal direction) of the liquid crystal layer.

### <<Layer 753 Containing Liquid Crystal Material>>

For example, thermotropic liquid crystal, low-molecular liquid crystal, high-molecular liquid crystal, polymer dispersed liquid crystal, ferroelectric liquid crystal, anti-ferroelectric liquid crystal, or the like can be used for the layer containing a liquid crystal material. Furthermore, a liquid crystal material which exhibits a cholesteric phase, a smectic phase, a cubic phase, a chiral nematic phase, an isotropic phase, or the like can be used. Furthermore, a liquid crystal material which exhibits a blue phase can be used.

<<First Electrode 751(i, j)>>

For example, the material that is used for the wiring or the like can be used for the first electrode 751(i, j). Specifically, a reflective film can be used for the first electrode 751(i, j). For example, a material in which a light-transmitting conductive material and a reflective film having an opening are stacked can be used for the first electrode 751(i, j).

### <<Reflective Film>>

For example, a material that reflects visible light can be used for the reflective film. Specifically, a material containing silver can be used for the reflective film. For example, a material containing silver, palladium, and the like or a material containing silver, copper, and the like can be used for the reflective film.

The reflective film reflects light that passes through the layer 753 containing a liquid crystal material, for example. This allows the first display element 750 to serve as a reflective liquid crystal element. Furthermore, for example, a material with unevenness on its surface can be used for the reflective film. In that case, incident light can be reflected in various directions so that a white image can be displayed.

Note that the first electrode 751(i, j) is not necessarily used for the reflective film. For example, the reflective film can be provided between the layer 753 containing a liquid crystal material and the first electrode 751(i, j). Alternatively, the first electrode 751(i, j) having a light-transmitting property can be provided between the reflective film and the layer 753 containing a liquid crystal material.

### <<Opening 751H, Region 751E>>

The opening 751H or the region 751E may have a polygonal shape, a quadrangular shape, an elliptical shape, a circular shape, a cross shape, a stripe shape, a slit-like shape, or a checkered pattern.

Furthermore, a single opening or a group of openings can be used as the opening 751H.

If the ratio of the total area of the opening 751H to the total area except for the openings is too high, display performed using the first display element 750(i, j) is dark.

If the ratio of the total area of the opening 751H to the total area except for the openings is too low, display performed using the second display element 550(i, j) is dark.

### <<Second Electrode 752>>

For example, a material having a visible-light-transmitting property and conductivity can be used for the second electrode 752.

For example, a conductive oxide, a metal film thin enough to transmit light, or a metal nanowire can be used for the second electrode 752.

Specifically, a conductive oxide containing indium can be used for the second electrode 752. Alternatively, a metal thin film with a thickness greater than or equal to 1 nm and less than or equal to 10 nm can be used for the second electrode 752. Alternatively, a metal nanowire containing silver can be used for the second electrode 752.

Specifically, indium oxide, indium tin oxide, indium zinc oxide, zinc oxide, zinc oxide to which gallium is added, zinc oxide to which aluminum is added, or the like can be used for the second electrode 752.

### <<Alignment Films AF1 and AF2>>

The alignment films AF1 and AF2 can be formed using a material containing polyimide or the like, for example. Specifically, a material formed by rubbing treatment or an optical alignment technique so that a liquid crystal material has alignment in a predetermined direction can be used.

For example, a film containing soluble polyimide can be used as the alignment film AF1 or AF2. In this case, the temperature required in forming the alignment film AF1 can be low. Accordingly, damage to other components at the time of forming the alignment film AF1 can be suppressed.

### <<Coloring Films CF1 and CF2>>

A material transmitting light of a predetermined color can be used for the coloring film CF1 or the coloring film CF2. Thus, the coloring film CF1 or the coloring film CF2 can be used as a color filter, for example. For example, a material that transmits blue light, green light, or red light can be used for the coloring film CF1 or the coloring film CF2. Furthermore, a material that transmits yellow light, white light, or the like can be used for the coloring film.

Note that a material having a function of converting the emitted light to a predetermined color light can be used for the coloring film CF2. Specifically, quantum dots can be used for the coloring film CF2. Thus, display with high color purity can be achieved.

### <<Light-Blocking Film BM>>

The light-blocking film BM can be formed with a material that prevents light transmission and can thus be used as a black matrix, for example.

### <<Insulating Film 771>>

The insulating film 771 can be formed of polyimide, an epoxy resin, an acrylic resin, or the like, for example.

### <<Functional Film 770P, Functional Film 770D>>

For example, an anti-reflection film, a polarizing film, a retardation film, a light diffusion film, a condensing film, or the like can be used as the functional film 770P or the functional film 770D.

Specifically, a film containing a dichromatic pigment can be used as the functional film 770P or the functional film 770D. Furthermore, a material having a pillar-shaped structure with an axis in a direction that intersects a surface of the substrate can be used for the functional film 770P or the functional film 770D. This makes it easy to transmit light in a direction along the axis and to scatter light in the other directions.

Alternatively, an antistatic film preventing the attachment of a foreign substance, a water repellent film suppressing the attachment of stain, a hard coat film suppressing a scratch in use, or the like can be used as the functional film 770P.

Specifically, a circularly polarizing film can be used as the functional film 770P. Further, a light diffusion film can be used as the functional film 770D.

<<Second Display Element 550(i, j)>>

For example, the second display element 550(i, j) can be a light-emitting element. Specifically, an organic electroluminescent element, an inorganic electroluminescent element, a light-emitting diode, or the like can be used as the second display element 550(i, j).

For example, a light-emitting organic compound can be used for the layer 553(j) containing a light-emitting material.

For example, quantum dots can be used for the layer 553(j) containing a light-emitting material. Accordingly, the half width becomes narrow, and light of a bright color can be emitted.

For example, a layered material for emitting blue light, green light, or red light, or the like can be used for the layer 553(j) containing a light-emitting material.

For example, a belt-like layered material that extends in the column direction along the signal line S2(j) can be used for the layer 553(j) containing a light-emitting material.

Alternatively, a layered material for emitting white light can be used for the layer 553(j) containing a light-emitting material. Specifically, a layered material in which a layer containing a light-emitting material including a fluorescent material that emits blue light, and a layer containing a material that is other than a fluorescent material and that emits green light and/or red light or a layer containing a material that is other than a fluorescent material and that emits yellow light are stacked can be used for the layer 553(j) containing a light-emitting material.

For example, a material that can be used for the wiring or the like can be used for the third electrode 551(i, j).

For example, a material that transmits visible light selected from materials that can be used for the wiring or the like can be used for the third electrode 551(i, j).

Specifically, conductive oxide, indium-containing conductive oxide, indium oxide, indium tin oxide, indium zinc oxide, zinc oxide, zinc oxide to which gallium is added, or the like can be used for the third electrode 551(i, j). Alternatively, a metal film that is thin enough to transmit light can be used as the third electrode 551(i, j). Further alternatively, a metal film that transmits part of light and reflects another part of light can be used as the third electrode 551(i, j). Thus, the second display element 550(i, j) can be provided with a microcavity structure. Consequently, light of a predetermined wavelength can be extracted more efficiently than light of the other wavelengths.

For example, a material that can be used for the wiring or the like can be used for the fourth electrode 552. Specifically, a material that reflects visible light can be used for the fourth electrode 552.

### <<Driver Circuit GD>>

Any of a variety of sequential circuits, such as a shift register, can be used as the driver circuit GD. For example, the transistor MD, a capacitor, and the like can be used in the driver circuit GD. Specifically, a transistor including a semiconductor film that can be formed in the same process as the semiconductor film of the transistor M or the transistor which can be used as the switch SW1 can be used.

As the transistor MD, a transistor having a different structure from the transistor that can be used as the switch SW1 can be used, for example. Specifically, a transistor including the conductive film 524 can be used as the transistor MD (see FIG. 12B).

The conductive film 524 is provided such that the semiconductor film 508 is sandwiched between the conductive films 504 and 524. The insulating film 516 is provided between the conductive film 524 and the semiconductor film 508. The insulating film 506 is provided between the semiconductor film 508 and the conductive film 504. For example, the conductive film 524 is electrically connected to a wiring that supplies the same potential as that supplied to the conductive film 504.

Note that the transistor MD can have the same structure as the transistor M.

### <<Driver Circuit SD>>

The driver circuit SD has a function of supplying an image signal based on the information V11 or the information V12. For example, the driver circuit SD described in Embodiment 1 can be used.

### <Method for Controlling Resistivity of Oxide Semiconductor Film>

A method for controlling the resistivity of an oxide semiconductor film will be described.

An oxide semiconductor film with a certain resistivity can be used as the semiconductor film 508, the conductive film 524, or the like.

For example, a method for controlling the concentration of impurities such as hydrogen and water contained in the oxide semiconductor film and/or the oxygen vacancies in the film can be used as the method for controlling the resistivity of an oxide semiconductor film.

Specifically, plasma treatment can be used as a method for increasing or decreasing the concentration of impurities such as hydrogen and water and/or the oxygen vacancies in the film.

Specifically, plasma treatment using a gas containing one or more kinds selected from a rare gas (He, Ne, Ar, Kr, or Xe), hydrogen, boron, phosphorus, and nitrogen can be employed. For example, plasma treatment in an Ar atmosphere, plasma treatment in a mixed gas atmosphere of Ar and hydrogen, plasma treatment in an ammonia atmosphere, plasma treatment in a mixed gas atmosphere of Ar and ammonia, or plasma treatment in a nitrogen atmosphere can be employed. Thus, the oxide semiconductor film can have a high carrier density and a low resistivity.

Alternatively, hydrogen, boron, phosphorus, or nitrogen is added to the oxide semiconductor film by an ion implantation method, an ion doping method, a plasma immersion ion implantation method, or the like, so that the oxide semiconductor film can have a low resistivity.

Alternatively, an insulating film containing hydrogen is formed in contact with the oxide semiconductor film, and the hydrogen is diffused from the insulating film to the oxide semiconductor film, so that the oxide semiconductor film can have a high carrier density and a low resistivity.

For example, an insulating film with a hydrogen concentration of greater than or equal to 1×10²² atoms/cm³ is formed in contact with the oxide semiconductor film, whereby hydrogen can be effectively supplied to the oxide semiconductor film. Specifically, a silicon nitride film can be used as the insulating film formed in contact with the oxide semiconductor film.

Hydrogen contained in the oxide semiconductor film reacts with oxygen bonded to a metal atom to be water, and an oxygen vacancy is formed in a lattice from which oxygen is released (or a portion from which oxygen is released). Due to entry of hydrogen into the oxygen vacancy, an electron serving as a carrier is generated in some cases. Furthermore, bonding of part of hydrogen to oxygen bonded to a metal atom causes generation of an electron serving as a carrier in some cases. Thus, the oxide semiconductor film can have a high carrier density and a low resistivity.

Specifically, an oxide semiconductor with a hydrogen concentration measured by secondary ion mass spectrometry (SIMS) of greater than or equal to 8×10¹⁹ atoms/cm³, preferably greater than or equal to 1×10²⁰ atoms/cm³, further preferably greater than or equal to 5×10²⁰ atoms/cm³ can be suitably used for the conductive film 524.

Meanwhile, an oxide semiconductor with a high resistivity can be used for a semiconductor film where a channel of a transistor is formed, specifically, the semiconductor film 508.

For example, an insulating film containing oxygen, in other words, an insulating film capable of releasing oxygen, is formed in contact with an oxide semiconductor, and the oxygen is supplied from the insulating film to the oxide semiconductor film, so that oxygen vacancies in the film or at the interface can be filled. Thus, the oxide semiconductor film can have a high resistivity.

For example, a silicon oxide film or a silicon oxynitride film can be used as the insulating film capable of releasing oxygen.

The oxide semiconductor film in which oxygen vacancies are filled and the hydrogen concentration is reduced can be referred to as a highly purified intrinsic or substantially highly purified intrinsic oxide semiconductor film. The term “substantially intrinsic” refers to the state in which an oxide semiconductor film has a carrier density lower than 8×10¹¹/cm³, preferably lower than 1×10¹¹/cm³, further preferably lower than 1×10¹⁰/cm³. A highly purified intrinsic or substantially highly purified intrinsic oxide semiconductor film has few carrier generation sources and thus can have a low carrier density. The highly purified intrinsic or substantially highly purified intrinsic oxide semiconductor film has a low density of defect states and accordingly can have a low density of trap states.

Furthermore, a transistor including the highly purified intrinsic or substantially highly purified intrinsic oxide semiconductor film has an extremely low off-state current; even when an element has a channel width of 1×10⁶ μm and a channel length L of 10 μm, the off-state current can be lower than or equal to the measurement limit of a semiconductor parameter analyzer, that is, lower than or equal to 1×10⁻¹³ A, at a voltage (drain voltage) between a source electrode and a drain electrode of from 1 V to 10 V.

The transistor in which a channel region is formed in the oxide semiconductor film that is a highly purified intrinsic or substantially highly purified intrinsic oxide semiconductor film can have a small change in electrical characteristics and high reliability.

Specifically, an oxide semiconductor whose hydrogen concentration measured by secondary ion mass spectrometry (SIMS) is lower than or equal to 2×10²⁰ atoms/cm³, preferably lower than or equal to 5×10¹⁹ atoms/cm³, further preferably lower than or equal to 1×10¹⁹ atoms/cm³, further preferably lower than 5×10¹⁸ atoms/cm³, further preferably lower than or equal to 1×10¹⁸ atoms/cm³, further preferably lower than or equal to 5×10¹⁷ atoms/cm³, further preferably lower than or equal to 1×10¹⁶ atoms/cm³ can be favorably used as a semiconductor where a channel of a transistor is formed.

Note that an oxide semiconductor film that has a higher hydrogen concentration and/or a larger number of oxygen vacancies and that has a lower resistivity than the semiconductor film 508 is used as the conductive film 524.

A film whose hydrogen concentration is twice or more, preferably ten times or more that of the semiconductor film 508 can be used as the conductive film 524.

A film whose resistivity is greater than or equal to 1×10⁻⁸ times and less than 1×10⁻¹ times that of the semiconductor film 508 can be used as the conductive film 524.

Specifically, a film whose resistivity is higher than or equal to 1×10⁻³ Ωcm and lower than 1×10⁴ Ωcm, preferably higher than or equal to 1×10⁻³ Ωcm and lower than 1×10⁻¹ Ωcm can be used as the conductive film 524.

### <<Substrate 710>>

A light-transmitting material can be used for the substrate 710, for example. Specifically, a material selected from the materials that can be used for the substrate 570 can be used for the substrate 710.

For example, aluminosilicate glass, tempered glass, chemically tempered glass, sapphire, or the like can be favorably used for the substrate 710 that is provided on the user side of the display panel. This can prevent damage or a crack of the display panel caused by the use thereof.

<<Sensing Element 775(g, h)>>

As the sensing element 775(g, h), an element that senses electrostatic capacitance, illuminance, magnetic force, a radio wave, pressure, or the like and supplies information based on the sensed physical value can be used, for example.

Specifically, a capacitor, a photoelectric conversion element, a magnetic sensing element, a piezoelectric element, a resonator, or the like can be used as the sensing element 775(g, h).

When a finger or the like having a higher dielectric constant than that of the air approaches a conductive film in the air, for example, electrostatic capacitance between the finger and the conductive film changes. This electrostatic capacitance change can be sensed, and the sensed information can be supplied. Specifically, a self-capacitive sensing element can be used.

The electrode C(g) and the electrode M(h) can be used for the sensing element, for example. Specifically, the electrode C(g) to which a control signal is supplied and the electrode M(h) that is positioned so that an electric field part of which is blocked by an approaching object is generated between the electrode M(h) and the electrode C(g) can be used. Thus, the electric field that is changed when blocked by the approaching object can be sensed using the potential of the sensor signal line ML(h), and a sensor signal can be supplied. As a result, the approaching object that blocks the electric field can be sensed. Specifically, a mutual capacitive sensing element can be used.

<<Control Line CL(g), Sensor Signal Line ML(h), Conductive Film BR(g, h)>>

For the control line CL(g), the sensor signal line ML(h), or the conductive film BR(g, h), a material having a visible-light-transmitting property and conductivity can be used, for example.

Specifically, a material used for the second electrode 752 can be used for the control line CL(g), the sensor signal line ML(h), or the conductive film BR(g, h).

### <<Insulating Film 706>>

A material that can be used for the insulating film 521 can be used for the insulating film 706 or the like, for example. Specifically, a film containing silicon and oxygen can be used for the insulating film 706.

### <<Terminal 719>>

A material that can be used for the wiring or the like can be used for the terminal 719, for example. Note that the terminal 719 can be electrically connected to a flexible printed circuit FPC2 using a conductive material ACF2, for example (see FIG. 13A).

Note that a control signal can be supplied to the control line CL(g) using the terminal 719. Alternatively, a sensor signal can be supplied from the sensor signal line ML(h).

### <<Bonding Layer 709>>

A material that can be used for the sealing material 705 can be used for the bonding layer 709, for example.

### <Structure Example 2 of Input/Output Device>

Another structure of the input/output device of one embodiment of the present invention will be described with reference to FIGS. 16A, 16B-1, and 16B-2, FIGS. 17A and 17B, and FIG. 18.

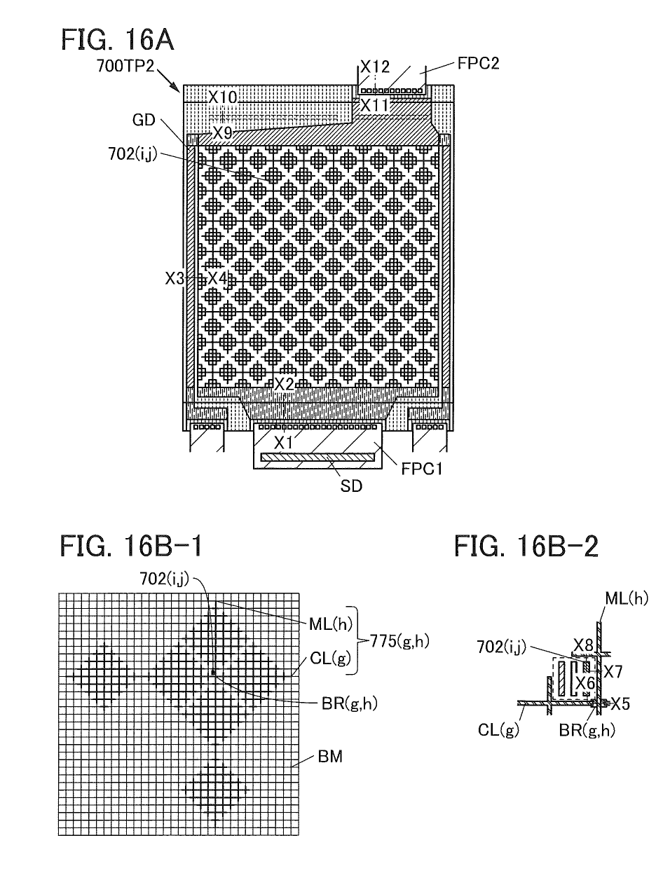

FIGS. 16A, 16B-1, and 16B-2 illustrate the structure of an input/output device 700TP2 of one embodiment of the present invention. FIG. 16A is a top view of the input/output device of one embodiment of the present invention. FIG. 16B-1 is a schematic diagram illustrating part of an input portion of the input/output device of one embodiment of the present invention. FIG. 16B-2 is a schematic diagram illustrating part of FIG. 16B-1.

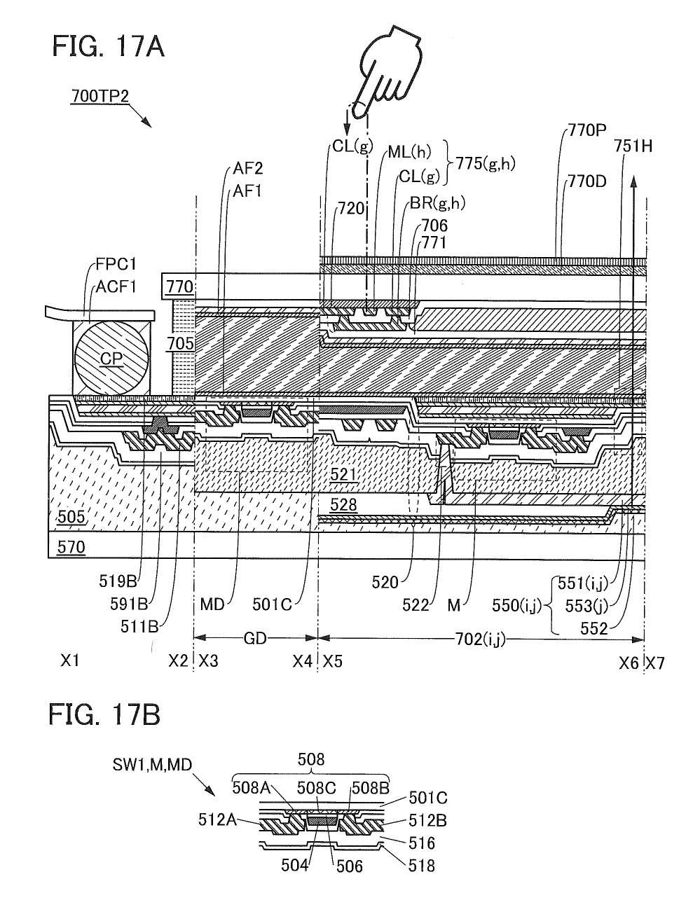

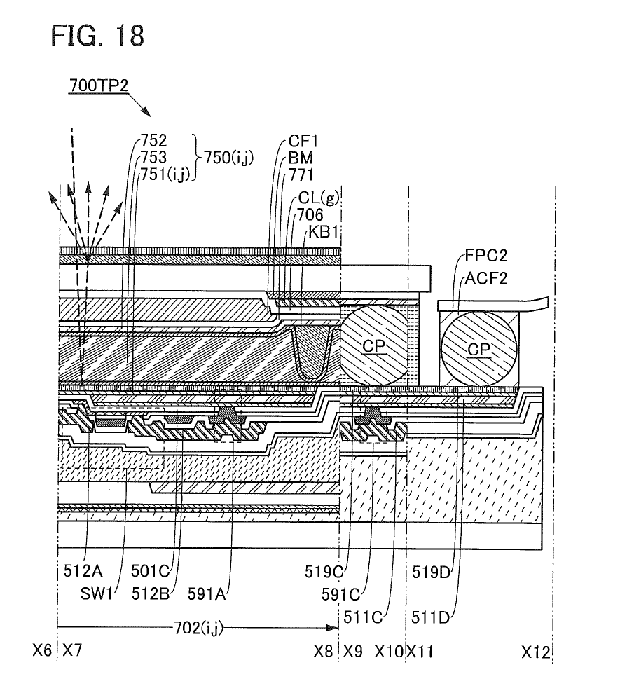

FIGS. 17A and 17B and FIG. 18 illustrate the structure of the input/output device of one embodiment of the present invention. FIG. 17A is a cross-sectional view taken along lines X1-X2 and X3-X4 in FIG. 16A and line X5-X6 in FIG. 16B-2. FIG. 17B is a cross-sectional view illustrating part of the structure illustrated in FIG. 17A.

FIG. 18 is a cross-sectional view taken along line X7-X8 in FIG. 16B-2 and lines X9-X10 and X11-X12 in FIG. 16A.

Note that the input/output device 700TP2 is different from the touch panel 700TP1, which is described with reference to FIGS. 10A, 10B-1, 10B-2, and 10C, FIGS. 11A and 11B, FIGS. 12A and 12B, and FIGS. 13A and 13B, in that a top-gate transistor is included; the functional layer 720 including the input portion is included in a region surrounded by the substrate 770, the insulating film 501C, and the sealing material 705; the electrode C(g) including an opening in a region overlapping with the pixel is included; the electrode M(h) including an opening in a region overlapping with the pixel is included; a conductive film 511D electrically connected to the control line CL(g) or the sensor signal line ML(h) is included; and a terminal 519D electrically connected to the conductive film 511D is included. Here, the different portions will be described in detail, and the above description is referred to for the other similar portions.

In the input/output device described in this embodiment, the control line CL(g) is electrically connected to the electrode C(g) provided with the opening, and the sensor signal line ML(h) is electrically connected to the electrode M(h) provided with the opening. The openings include the regions overlapping with the pixel. An opening of a conductive film included in the control line CL(g) includes a region overlapping with the pixel 702(i, j), for example (see FIGS. 16B-1 and 16B-2 and FIG. 17A).

In the input/output device described in this embodiment, the gap between the control line CL(g) and the second electrode 752 or between the sensor signal line ML(h) and the second electrode 752 is greater than or equal to 0.2 μm and less than or equal to preferably greater than or equal to 1 μm and less than or equal to 8 and further preferably greater than or equal to 2.5 μm and less than or equal to 4 μm.

The input/output device of one embodiment of the present invention includes the first electrode provided with the opening in the region overlapping with the pixel and the second electrode provided with the opening in the region overlapping with the pixel. Accordingly, an object that comes in the vicinity a region overlapping with the display panel can be sensed without disturbing display of the display panel. Furthermore, the thickness of the input/output device can be reduced. As a result, a novel input/output device that is highly convenient or reliable can be provided.

In the input/output device described in this embodiment, the functional layer 720 is provided in the region surrounded by the substrate 770, the insulating film 501C, and the sealing material 705. Thus, the input/output device can be formed without using the substrate 710 and the bonding layer 709.

The input/output device described in this embodiment includes the conductive film 511D (see FIG. 18).

Note that the conductive material CP or the like can be provided between the control line CL(g) and the conductive film 511D to electrically connect the control line CL(g) and the conductive film 511D. Alternatively, the conductive material CP or the like can be provided between the sensor signal line ML(h) and the conductive film 511D to electrically connect the sensor signal line ML(h) and the conductive film 511D.

The input/output device described in this embodiment also includes the terminal 519D electrically connected to the conductive film 511D. The terminal 519D is provided with the conductive film 511D and an intermediate film 754D, and the intermediate film 754D includes a region in contact with the conductive film 511D.

Note that the terminal 519D can be electrically connected to the flexible printed circuit FPC2 using the conductive material ACF2, for example. Accordingly, a control signal can be supplied to the control line CL(g) using the terminal 519D, or a sensor signal can be supplied from the sensor signal line ML(h) using the terminal 519D, for example.

### <<Conductive Film 511D>>

A material that can be used for the wiring or the like can be used for the conductive film 511D, for example.

### <<Terminal 519D>>

A material that can be used for the wiring or the like can be used for the terminal 519D, for example. Specifically, the terminal 519D can have the same structure as the terminal 519B or the terminal 519C. Note that for example, the terminal 519D can be electrically connected to a flexible printed circuit FPC2 using a conductive material ACF2, for example (see FIGS. 13A and 13B).

### <<Switch SW1, Transistor M, Transistor MD>>

A transistor that can be used as a switch SW1, a transistor M, and a transistor MD each include the conductive film 504 having a region overlapping with the insulating film 501C and the semiconductor film 508 having a region sandwiched between the insulating film 501C and the conductive film 504. Note that the conductive film 504 functions as a gate electrode (see FIG. 17B).

The semiconductor film 508 includes a first region 508A, a second region 508B, and a third region 508C. The first region 508A and the second region 508B do not overlap with the conductive film 504. The third region 508C is positioned between the first region 508A and the second region 508B and overlaps with the conductive film 504.

The transistor MID includes the insulating film 506 between the third region 508C and the conductive film 504. Note that the insulating film 506 functions as a gate insulating film.

The first region 508A and the second region 508B have a lower resistivity than that of the third region 508C, and function as a source region and a drain region.

Note that, for example, the method for controlling the resistivity of an oxide semiconductor film, which is described in detail above, can be used to form the first region 508A and the second region 508B in the semiconductor film 508. Specifically, plasma treatment using a gas containing a rare gas can be employed.

The conductive film 504 can be used as a mask, for example, in which case a part of the third region 508C can be self-aligned to an end portion of the conductive film 504.

The transistor MID includes the conductive film 512A and the conductive film 512B that are in contact with the first region 508A and the second region 508B, respectively. The conductive film 512A and the conductive film 512B function as a source electrode and a drain electrode.

A transistor that can be fabricated in the same process as the transistor MD can be used as the transistor M.

Note that this embodiment can be combined with any of the other embodiments in this specification as appropriate.

### Embodiment 3

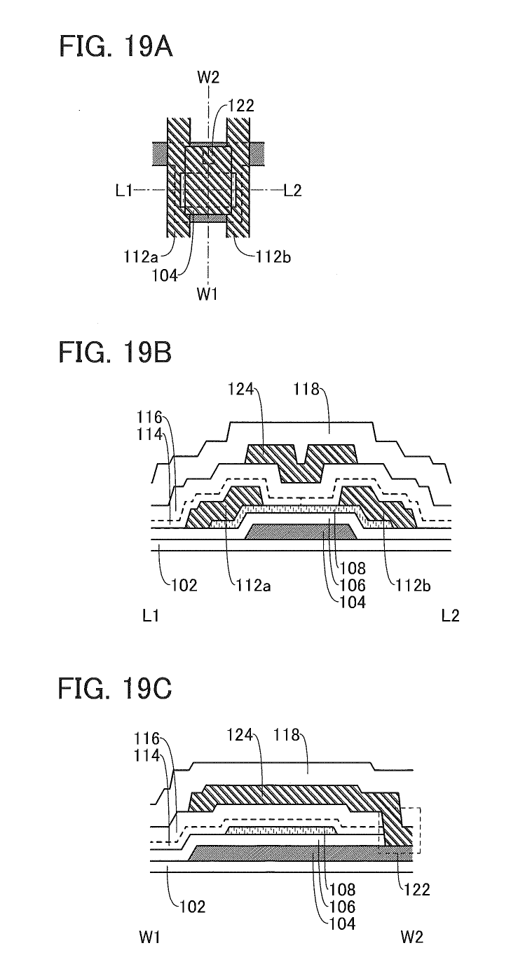

In this embodiment, a structure of a transistor that can be used in the input/output device of one embodiment of the present invention will be described with reference to FIGS. 19A to 19C.

FIGS. 19A to 19C illustrate a structure of a transistor TR which can be used in the input/output device of one embodiment of the present invention. FIG. 19A is a top view illustrating a transistor which can be used as the transistor TR which can be used in the input/output device of one embodiment of the present invention. FIG. 19B is a cross-sectional view illustrating the transistor in a channel length (L) direction of FIG. 19A. FIG. 19C is a cross-sectional view including the transistor in a channel width (W) direction of FIG. 19A. In some cases, the direction of line L1-L2 is referred to as a channel length direction and the direction of line W1-W2 is referred to as a channel width direction.

Note that the transistor TR can be used in the input/output device or the like described in Embodiment 2.

For example, when the transistor TR is used as the switch SW1, an insulating film 102, a conductive film 104, an insulating film 106, a semiconductor film 108, a conductive film 112a, a conductive film 112b, a stacked film of an insulating film 114 and an insulating film 116, and an insulating film 118 can be referred to as the second insulating film 501C, the conductive film 504, the insulating film 506, the semiconductor film 508, the conductive film 512A, the conductive film 512B, the insulating film 516, and the insulating film 518, respectively.

### <Structure Example 1 of Transistor>

The transistor which can be used in the input/output device of one embodiment of the present invention includes the conductive film 104 over the second insulating film 102, the insulating film 106 over the second insulating film 102 and the conductive film 104, the semiconductor film 108 over the insulating film 106, a conductive film 112b over the semiconductor film 108, the conductive film 112a over the semiconductor film 108, the insulating film 114 over the semiconductor film 108, the conductive film 112a, and the conductive film 112b, the insulating film 116 over the insulating film 114, and a conductive film 124 over the insulating film 116 (see FIG. 19B).

For example, the conductive film 104 serves as the first gate electrode, the conductive film 112b serves as the source electrode, the conductive film 112a serves as the drain electrode, and the conductive film 124 serves as the second gate electrode. In addition, the insulating film 106 serves as a first gate insulating film and the insulating films 114 and 116 serve as second gate insulating films.

For example, an oxide semiconductor can be used for the semiconductor film 108. Specifically, an oxide semiconductor film containing indium or an oxide semiconductor film containing indium, gallium, and zinc can be used for the semiconductor film 108.

In addition, the semiconductor film 108 includes In, M (M is Al, Ga, Y, or Sn), and Zn.

The semiconductor film 108 preferably includes a region in which the atomic proportion of In is larger than the atomic proportion of M for example. Note that the semiconductor device of one embodiment of the present invention is not limited thereto: The semiconductor film 108 may include a region in which the atomic proportion of In is smaller than the atomic proportion of M or may include a region in which the atomic proportion of In is equal to the atomic proportion of M.

The semiconductor film 108 preferably includes a region in which the atomic proportion of In is larger than the atomic proportion of M. Thus, the field effect mobility of the transistor can be increased. Specifically, the field-effect mobility of the transistor can exceed 10 cm²/Vs, preferably exceed 30 cm²/Vs.

### <<Effect of Two Gate Electrodes>>

The transistor which can be used in the input/output device of one embodiment of the present invention can include two gate electrodes.

The effect of two gate electrodes on the characteristics of the transistor is described with reference to FIG. 19C.

As shown in FIG. 19C, the conductive film 124 serving as the second gate electrode is electrically connected to the conductive film 104 serving as the first gate electrode in an opening 122. Accordingly, the conductive film 104 and the conductive film 124 are supplied with the same potential.

As shown in FIG. 19C, the semiconductor film 108 is positioned so as to face the conductive film 104 and the conductive film 124, and is sandwiched between the two conductive films serving as the gate electrodes.

The length in the channel width direction of each of the conductive film 104 and the conductive film 124 is longer than that of the semiconductor film 108. Furthermore, the entire semiconductor film 108 is covered with the conductive film 104 and the conductive film 124 with the insulating films 106, 114, and 116 provided therebetween.

In other words, the conductive film 104 and the conductive film 124 are connected in the opening 122 which is provided in the insulating films 106, 114, and 116 and each include a region located outward from the side end portion of the semiconductor film 108.

With such a structure, the semiconductor film 108 included in the transistor can be electrically surround by electric fields of the conductive film 104 and the conductive film 124. A device structure of a transistor in which electric fields of a first gate electrode and a second gate electrode electrically surround an oxide semiconductor film where a channel region is formed can be referred to as a surrounded channel (S-channel) structure.

Since the transistor has the S-channel structure, an electric field for inducing a channel can be effectively applied to the semiconductor film 108 by the conductive film 104 functioning as the first gate electrode; therefore, the current drive capability of the transistor can be improved and high on-state current characteristics can be obtained. Since the on-state current can be increased, the size of the transistor can be reduced. In addition, since the transistor has a structure in which the semiconductor film 108 is surrounded by the conductive film 104 serving as the first gate electrode and the conductive film 124 serving as the second gate electrode, the mechanical strength of the transistor can be increased.

Although the structure in which the first gate electrode is electrically connected to the second gate electrode is described above, one embodiment of the present invention is not limited thereto. For example, the conductive film 524 serving as the second gate electrode may be electrically connected to the conductive film 512B serving as the source electrode or the drain electrode of the transistor M.

Note that this embodiment can be combined with any of the other embodiments in this specification as appropriate.

### Embodiment 4

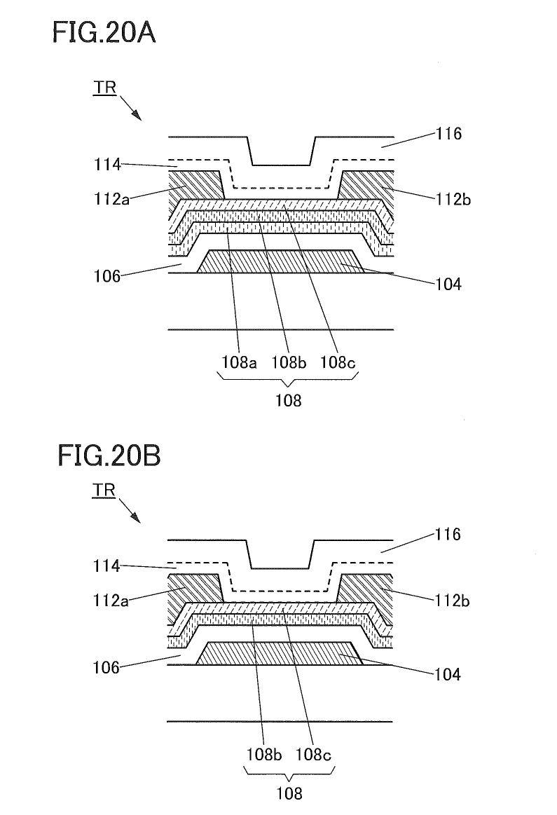

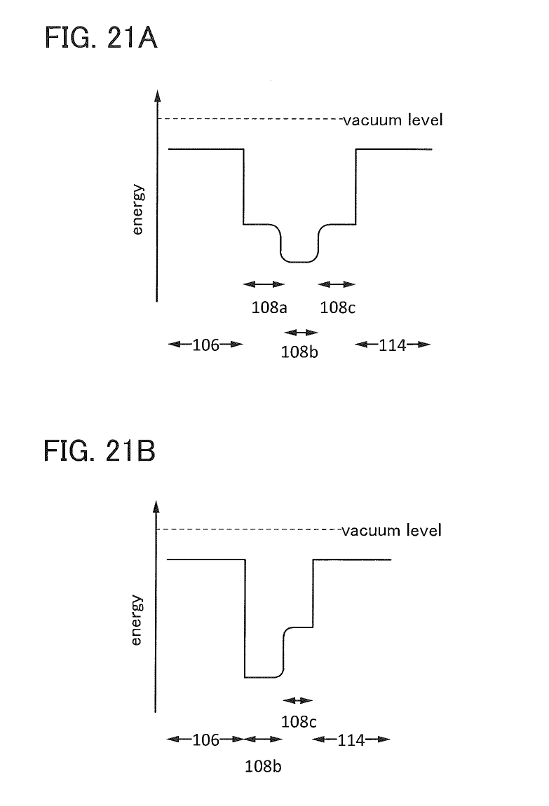

In this embodiment, structures of a transistor that can be used in the information processing device of one embodiment of the present invention will be described with reference to FIGS. 20A and 20B and FIGS. 21A and 21B. Specifically, a structure of an oxide semiconductor film which can be used as a semiconductor film of a transistor will be described below.

For example, the transistor described in this embodiment can be used as the switch SW1, the switch SW2, the transistor M, or the transistor MD.

FIGS. 20A and 20B are cross-sectional views of the transistors in the channel length (L) direction. FIG. 20A is a cross-sectional view in the channel length (L) direction of a transistor including an oxide semiconductor film in which three films are stacked. FIG. 20B is a cross-sectional view in the channel length (L) direction of a transistor including an oxide semiconductor film in which two films are stacked.

FIGS. 21A and 21B are schematic views each illustrating a band structure of stacked films. Stacked films include oxide semiconductor films and insulating films in contact with the oxide semiconductor film. For easy understanding, the band structure shows the energy level of the conduction band minimum (E_{c}) of each of the oxide semiconductor films and the insulating films included in the stacked-layer film.

FIG. 21A illustrates an example of a band structure in the thickness direction of a stack including the insulating film 106, the semiconductor films 108a, 108b, and 108c, and the insulating film 114.

FIG. 21B illustrates an example of a band structure in the thickness direction of a stack including the insulating film 106, the semiconductor films 108b and 108c, and the insulating film 114.

### <Structural Example 1 of Semiconductor Device>

For example, a semiconductor film which includes three films and is sandwiched between two insulating films can be used for the transistor. Specifically, a semiconductor film which includes the semiconductor films 108a, 108b, and 108c and are sandwiched between the insulating film 106 and the insulating film 116 can be used (see FIG. 20A and FIG. 21A).

The semiconductor film 108c includes a region overlapping with the semiconductor film 108a and the semiconductor film 108b includes a region sandwiched between the semiconductor film 108a and the semiconductor film 108c.

The insulating film 116 includes a region overlapping with the insulating film 106.

The semiconductor film 108a includes a region in contact with the insulating film 106, the semiconductor film 108c includes a region in contact with the insulating film 116, and the regions overlap with each other.

FIG. 21A is a band diagram of a structure in which a silicon oxide film is used as each of the insulating films 106 and 114, an oxide semiconductor film formed using a metal oxide target having an atomic ratio of metal elements of In:Ga:Zn=1:3:2 is used as the semiconductor film 108a, an oxide semiconductor film formed using a metal oxide target having an atomic ratio of metal elements of In:Ga:Zn=4:2:4.1 is used as the semiconductor film 108b, and an oxide semiconductor film formed using a metal oxide target having an atomic ratio of metal elements of In:Ga:Zn=1:3:2 is used as the semiconductor film 108c.

### <Structural Example 2 of Semiconductor Device>

For example, a semiconductor film which includes two films and is sandwiched between two insulating films can be used for the transistor. Specifically, an oxide semiconductor film which includes the semiconductor film 108b and the semiconductor film 108c and is sandwiched between the insulating film 106 and the insulating film 114 can be used for the transistor (see FIG. 20B and FIG. 21B).

The semiconductor film 108c includes a region overlapping with the semiconductor film 108a.

The insulating film 114 includes a region overlapping with the insulating film 106.

The semiconductor film 108b includes a region in contact with the insulating film 106 and the semiconductor film 108c includes a region in contact with the insulating film 114 and regions overlap with each other.

FIG. 21B is a band diagram of a structure in which a silicon oxide film is used as each of the insulating films 106 and 114, an oxide semiconductor film formed using a metal oxide target having an atomic ratio of metal elements of In:Ga:Zn=4:2:4.1 is used as the semiconductor film 108b, and a metal oxide film formed using a metal oxide target having an atomic ratio of metal elements of In:Ga:Zn=1:3:2 is used as the semiconductor film 108c.

### <Band Structure of Semiconductor Film>

As illustrated in FIGS. 21A and 21B, the energy level of the conduction band minimum gradually varies between the semiconductor film 108a and the semiconductor film 108b and between the semiconductor film 108b and the semiconductor film 108c. In other words, the energy level of the conduction band minimum is continuously varied or continuously connected. To obtain such a band structure, there exists no impurity, which forms a defect state such as a trap center or a recombination center, at the interface between the semiconductor film 108a and the semiconductor film 108b or at the interface between the semiconductor film 108b and the semiconductor film 108c.

To form a continuous junction between the semiconductor film 108a and the semiconductor film 108b and between the semiconductor film 108b and the semiconductor film 108c, the films are required to be formed successively without exposure to the air by using a multi-chamber deposition apparatus (sputtering apparatus) provided with a load lock chamber.

With the band structure of FIG. 21A or FIG. 21B, the semiconductor film 108b serves as a well, and a channel region is formed in the semiconductor film 108b in the transistor with the stacked-layer structure.

Note that by providing the semiconductor film 108a and/or the semiconductor film 108c, the semiconductor film 108b can be distanced away from trap states.

In addition, the trap states might be more distant from the vacuum level than the energy level of the conduction band minimum (E_{c}) of the semiconductor film 108b functioning as a channel region, so that electrons are likely to be accumulated in the trap states. When the electrons are accumulated in the trap states, the electrons become negative fixed electric charge, so that the threshold voltage of the transistor is shifted in the positive direction. Therefore, it is preferable that the trap states be closer to the vacuum level than the energy level of the conduction band minimum (E_{c}) of the semiconductor film 108b. Such a structure inhibits accumulation of electrons in the trap states. As a result, the on-state current and the field-effect mobility of the transistor can be increased.

The energy level of the conduction band minimum of each of the semiconductor films 108a and 108c is closer to the vacuum level than that of the semiconductor film 108b. Typically, a difference in energy level between the conduction band minimum of the semiconductor film 108b and the conduction band minimum of each of the semiconductor films 108a and 108c is 0.15 eV or more or 0.5 eV or more and 2 eV or less or 1 eV or less. That is, the difference between the electron affinity of each of the semiconductor films 108a and 108c and the electron affinity of the semiconductor film 108b is 0.15 eV or more or 0.5 eV or more and 2 eV or less or 1 eV or less.

In such a structure, the semiconductor film 108b serves as a main path of current and functions as a channel region. In addition, since the semiconductor films 108a and 108c each include one or more metal elements included in the semiconductor film 108b in which a channel region is formed, interface scattering is less likely to occur at the interface between the semiconductor film 108a and the semiconductor film 108b or at the interface between the semiconductor film 108b and the semiconductor film 108c. Thus, the transistor can have high field-effect mobility because the movement of carriers is not hindered at the interface.

To prevent each of the semiconductor films 108a and 108c from functioning as part of a channel region, a material having sufficiently low conductivity is used for the semiconductor films 108a and 108c. Alternatively, a material which has a smaller electron affinity (a difference in energy level between the vacuum level and the conduction band minimum) than the semiconductor film 108b and has a difference in energy level in the conduction band minimum from the semiconductor film 108b (band offset) is used for the semiconductor films 108a and 108c. Furthermore, to inhibit generation of a difference between threshold voltages due to the value of the drain voltage, it is preferable to form the semiconductor films 108a and 108c using a material whose energy level of the conduction band minimum is closer to the vacuum level than that of the semiconductor film 108b. For example, a difference in energy level between the conduction band minimum of the semiconductor film 108b and the conduction band minimum of the semiconductor films 108a and 108c is preferably 0.2 eV or more and further preferably 0.5 eV or more.

It is preferable that the semiconductor films 108a and 108c not have a spinel crystal structure. This is because if the semiconductor films 108a and 108c have a spinel crystal structure, constituent elements of the conductive films 112a and 112b might be diffused to the semiconductor film 108b at the interface between the spinel crystal structure and another region.

The thickness of each of the semiconductor films 108a and 108c is greater than or equal to a thickness that is capable of inhibiting diffusion of the constituent elements of the conductive films 112a and 112b to the semiconductor film 108b, and less than a thickness that inhibits supply of oxygen from the insulating film 114 to the semiconductor film 108b. For example, when the thickness of each of the semiconductor films 108a and 108c is greater than or equal to 10 nm, diffusion of the constituent elements of the conductive films 112a and 112b to the semiconductor film 108b can be inhibited. When the thickness of each of the semiconductor films 108a and 108c is less than or equal to 100 nm, oxygen can be effectively supplied from the insulating film 114 to the semiconductor film 108b.

When the semiconductor films 108a and 108c are each an In-M-Zn oxide in which the atomic proportion of M (M is Al, Ga, Y, or Sn) is higher than that of In, the energy gap of each of the semiconductor films 108a and 108c can be large and the electron affinity thereof can be small. Therefore, a difference in electron affinity between the oxide semiconductor film 108b and each of the oxide semiconductor films 108a and 108c may be controlled by the proportion of the element M. Furthermore, an oxygen vacancy is less likely to be generated in the oxide semiconductor film in which the atomic proportion of M is higher than that of In because M is a metal element that is strongly bonded to oxygen.

When an In-M-Zn oxide is used for the semiconductor films 108a and 108c, the proportions of In and M, not taking Zn and O into consideration, are preferably as follows: the atomic percentage of In is less than 50 atomic % and the atomic percentage of M is greater than 50 atomic %; and further preferably, the atomic percentage of In is less than 25 atomic % and the atomic percentage of M is greater than 75 atomic %. Alternatively, a gallium oxide film may be used as each of the semiconductor films 108a and 108c.

Furthermore, in the case where each of the semiconductor films 108a, 108b, and 108c is an In-M-Zn oxide, the proportion of M atoms in each of the semiconductor films 108a and 108c is higher than that in the semiconductor film 108b. Typically, the proportion of M atoms in each of the semiconductor films 108a and 108c is 1.5 or more times, preferably twice or more times, and further preferably three or more times as high as that in the oxide semiconductor film 108b.

Furthermore, in the case where the semiconductor films 108a, 108b, and 108c are each an In-M-Zn oxide, when the semiconductor film 108b has an atomic ratio of In:M:Zn=x₁:y₁:z₁ and the semiconductor films 108a and 108c each have an atomic ratio of In:M:Zn=x₂:y₂:z₂, y₂/x₂ is larger than y₁/x₁, preferably y₂/x₂ is 1.5 or more times as large as y₁/x₁, further preferably y₂/x₂ is two or more times as large as y₁/x₁, and still further preferably y₂/x₂ is three or more times or four or more times as large as y₁/x₁. At this time, y₁ is preferably greater than or equal to x₁ in the semiconductor film 108b, because stable electrical characteristics of a transistor including the semiconductor film 108b can be achieved. However, when y₁ is three or more times as large as x₁, the field-effect mobility of the transistor including the semiconductor film 108b is reduced. Accordingly, y₁ is preferably smaller than three times x₁.

In the case where the semiconductor film 108b is an In-M-Zn oxide and a target having the atomic ratio of metal elements of In:M:Zn=x₁:y₁:z₁ is used for depositing the semiconductor film 108b, x₁/y₁ is preferably greater than or equal to 1/3 and less than or equal to 6 and further preferably greater than or equal to 1 and less than or equal to 6, and z₁/y₁ is preferably greater than or equal to 1/3 and less than or equal to 6 and further preferably greater than or equal to 1 and less than or equal to 6.

In the case where the semiconductor films 108a and 108c are each an In-M-Zn oxide and a target having an atomic ratio of metal elements of In:M:Zn=x₂:y₂:z₂ is used for depositing the semiconductor films 108a and 108c, x₂/y₂ is preferably less than x₁/y₁, and z₂/y₂ is preferably greater than or equal to 1/3 and less than or equal to 6 and further preferably greater than or equal to 1 and less than or equal to 6. When the atomic ratio of M with respect to In is high, the energy gap of the semiconductor films 108a and 108c can be large and the electron affinity thereof can be small; therefore, y₂/x₂ is preferably higher than or equal to 3 or higher than or equal to 4. Typical examples of the atomic ratio of the metal elements of the target include In:M:Zn=1:3:2, In:M:Zn=1:3:4, In:M:Zn=1:3:5, In:M:Zn=1:3:6, In:M:Zn=1:4:2, In:M:Zn=1:4:4, In:M:Zn=1:4:5, and In:M:Zn=1:5:5.

Furthermore, in the case where the semiconductor films 108a and 108c are each an In-M oxide, when a divalent metal element (e.g., zinc) is not included as M, the semiconductor films 108a and 108c which do not include a spinel crystal structure can be formed. As the semiconductor films 108a and 108c, for example, an In—Ga oxide film can be used. The In—Ga oxide can be formed by a sputtering method using an In—Ga metal oxide target (In:Ga=7:93), for example. To deposit the semiconductor films 108a and 108c by a sputtering method using DC discharge, on the assumption that an atomic ratio of In:M is x:y, y/(x+y) is preferably less than or equal to 0.96 and further preferably less than or equal to 0.95, for example, 0.93.

In each of the semiconductor films 108a, 108b, and 108c, the proportions of the atoms in the above atomic ratio vary within a range of ±40% as an error.

This embodiment can be implemented in combination with any of the other embodiments in this specification as appropriate.

### Embodiment 5

In this embodiment, a semiconductor device (memory device) that can retain stored data even when not powered and that has an unlimited number of write cycles, and a CPU including the semiconductor device are described. The CPU described in this embodiment can be used for the information processing device described in Embodiment 1, for example.

### <Memory Device>

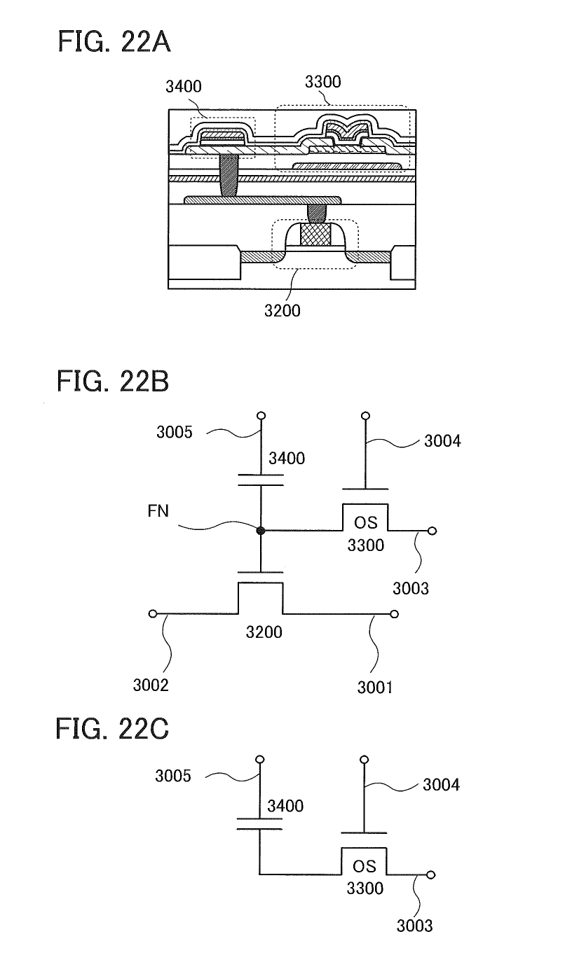

An example of a semiconductor device (memory device) that can retain stored data even when not powered and that has an unlimited number of write cycles is shown in FIGS. 22A to 22C. Note that FIG. 22B is a circuit diagram of the structure in FIG. 22A.

The semiconductor device illustrated in FIGS. 22A and 22B includes a transistor 3200 using a first semiconductor material, a transistor 3300 using a second semiconductor material, and a capacitor 3400.

The first and second semiconductor materials preferably have different energy gaps. For example, the first semiconductor material can be a semiconductor material other than an oxide semiconductor (examples of such a semiconductor material include silicon (including strained silicon), germanium, silicon germanium, silicon carbide, gallium arsenide, aluminum gallium arsenide, indium phosphide, gallium nitride, and an organic semiconductor), and the second semiconductor material can be an oxide semiconductor. A transistor using a material other than an oxide semiconductor, such as single crystal silicon, can operate at high speed easily. On the other hand, a transistor including an oxide semiconductor has a low off-state current.

The transistor 3300 is a transistor in which a channel is formed in a semiconductor layer including an oxide semiconductor. Since the off-state current of the transistor 3300 is small, stored data can be retained for a long period. In other words, power consumption can be sufficiently reduced because a semiconductor memory device in which refresh operation is unnecessary or the frequency of refresh operation is extremely low can be provided.

In FIG. 22B, a first wiring 3001 is electrically connected to a source electrode of the transistor 3200. A second wiring 3002 is electrically connected to a drain electrode of the transistor 3200. A third wiring 3003 is electrically connected to one of a source electrode and a drain electrode of the transistor 3300. A fourth wiring 3004 is electrically connected to a gate electrode of the transistor 3300. A gate electrode of the transistor 3200 and the other of the source electrode and the drain electrode of the transistor 3300 are electrically connected to one electrode of the capacitor 3400. A fifth wiring 3005 is electrically connected to the other electrode of the capacitor 3400.

The semiconductor device in FIG. 22A has a feature that the potential of the gate electrode of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to the gate electrode of the transistor 3200 and the capacitor 3400. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge supplied to the gate of the transistor 3200 is held (retaining).

Since the off-state current of the transistor 3300 is extremely small, the charge of the gate of the transistor 3200 is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the gate of the transistor 3200. This is because in the case of using an n-channel transistor as the transistor 3200, an apparent threshold voltage Vₜₕ_{_}_{H} at the time when the high-level charge is given to the gate electrode of the transistor 3200 is lower than an apparent threshold voltage Vₜₕ_{_}_{L} at the time when the low-level charge is given to the gate electrode of the transistor 3200. Here, an apparent threshold voltage refers to the potential of the fifth wiring 3005 that is needed to turn on the transistor 3200. Thus, the potential of the fifth wiring 3005 is set to a potential V₀ that is between Vₜₕ_{_}_{H} and Vₜₕ_{_}_{L}, whereby charge supplied to the gate of the transistor 3200 can be determined. For example, in the case where the high-level charge is supplied to the gate electrode of the transistor 3200 in writing and the potential of the fifth wiring 3005 is V₀ (>Vₜₕ_{_}_{H}), the transistor 3200 is turned on. In the case where the low-level charge is supplied to the gate electrode of the transistor 3200 in writing, even when the potential of the fifth wiring 3005 is V₀ (<Vₜₕ_{_}_{L}), the transistor 3200 remains off. Thus, the data retained in the gate electrode of the transistor 3200 can be read by determining the potential of the second wiring 3002.

Note that in the case where memory cells are arrayed, it is necessary that only data of a designated memory cell(s) can be read. For example, the fifth wiring 3005 of memory cells from which data is not read may be supplied with a potential at which the transistor 3200 is turned off regardless of the potential supplied to the gate electrode, that is, a potential lower than Vₜₕ_{_}_{H}, whereby only data of a designated memory cell(s) can be read. Alternatively, the fifth wiring 3005 of the memory cells from which data is not read may be supplied with a potential at which the transistor 3200 is turned on regardless of the potential supplied to the gate electrode, that is, a potential higher than Vₜₕ_{_}_{L}, whereby only data of a designated memory cell(s) can be read.

The semiconductor device illustrated in FIG. 22C is different from the semiconductor device illustrated in FIG. 22A in that the transistor 3200 is not provided. Also in this case, writing and retaining operation of data can be performed in a manner similar to those of the semiconductor device illustrated in FIG. 22A.

Next, reading of data of the semiconductor device illustrated in FIG. 22C is described. When the transistor 3300 is turned on, the third wiring 3003 that is in a floating state and the capacitor 3400 are electrically connected to each other, and the charge is redistributed between the third wiring 3003 and the capacitor 3400. As a result, the potential of the third wiring 3003 is changed. The amount of change in the potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the bit line BL in the case of retaining the potential V₁ (=(C_{B}×V_{B0}+C×V₁)/(C_{B}+C)) is higher than the potential of the bit line BL in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor material may be used for a driver circuit for driving a memory cell, and a transistor including the second semiconductor material may be stacked over the driver circuit as the transistor 3300.

When including a transistor in which a channel formation region is formed using an oxide semiconductor and which has an extremely small off-state current, the semiconductor device described in this embodiment can retain stored data for an extremely long time. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

Furthermore, in the semiconductor device described in this embodiment, high voltage is not needed for writing data and there is no problem of deterioration of elements. Unlike in a conventional nonvolatile memory, for example, it is not necessary to inject and extract electrons into and from a floating gate; thus, a problem such as deterioration of a gate insulating film is not caused. That is, the semiconductor device described in this embodiment does not have a limit on the number of times data can be rewritten, which is a problem of a conventional nonvolatile memory, and the reliability thereof is drastically improved. Furthermore, data is written depending on the state of the transistor (on or off), whereby high-speed operation can be easily achieved.

The above memory device can also be used in an LSI such as a digital signal processor (DSP), a custom LSI, or a programmable logic device (PLD) and a radio frequency identification (RF-ID) tag, in addition to a central processing unit (CPU), for example.

### <CPU>

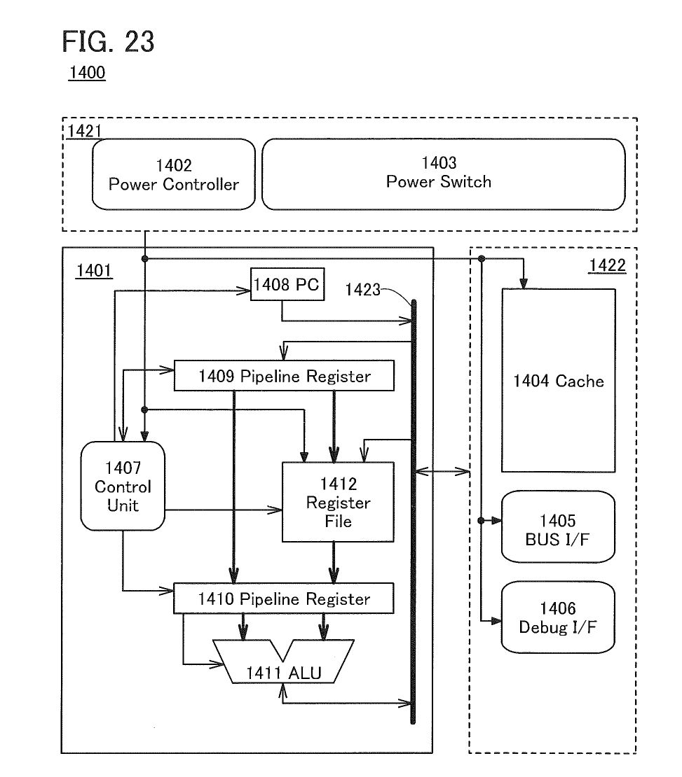

A semiconductor device 1400 shown in FIG. 23 includes a CPU core 1401, a power management unit 1421, and a peripheral circuit 1422. The power management unit 1421 includes a power controller 1402 and a power switch 1403. The peripheral circuit 1422 includes a cache 1404 including cache memory, a bus interface (BUS I/F) 1405, and a debug interface (Debug I/F) 1406. The CPU core 1401 includes a data bus 1423, a control unit 1407, a PC (program counter) 1408, a pipeline register 1409, a pipeline register 1410, an ALU (arithmetic logic unit) 1411, and a register file 1412. Data is transmitted between the CPU core 1401 and the peripheral circuit 1422 such as the cache 1404 via the data bus 1423.

The semiconductor device (cell) can be used for many logic circuits typified by the power controller 1402 and the control unit 1407, particularly to all logic circuits that can be constituted using standard cells. Accordingly, the semiconductor device 1400 can be small. The semiconductor device 1400 can have reduced power consumption. The semiconductor device 1400 can have a higher operating speed. The semiconductor device 1400 can have a smaller power supply voltage variation.

When p-channel Si transistors and the transistor described in the above embodiment which includes an oxide semiconductor (preferably an oxide containing In, Ga, and Zn) in a channel formation region are used in the semiconductor device (cell) and the semiconductor device (cell) is used in the semiconductor device 1400, the semiconductor device 1400 can be small. The semiconductor device 1400 can have reduced power consumption. The semiconductor device 1400 can have a higher operating speed. In particular, by using only a p-channel transistor as the Si-transistor, manufacturing cost can be reduced.

The control unit 1407 has functions of totally controlling operations of the PC 1408, the pipeline register 1409, the pipeline register 1410, the ALU 1411, the register file 1412, the cache 1404, the bus interface 1405, the debug interface 1406, and the power controller 1402 to decode and execute instructions contained in a program such as input applications.

The ALU 1411 has a function of performing a variety of arithmetic operations such as four arithmetic operations and logic operations.

The cache 1404 has a function of temporarily storing frequently-used data. The PC 1408 is a register having a function of storing an address of an instruction to be executed next. Note that although not shown in FIG. 23, the cache 1404 is provided with a cache controller for controlling the operation of the cache memory.

The pipeline register 1409 has a function of temporarily storing instruction data.

The register file 1412 includes a plurality of registers including a general purpose register and can store data that is read from the main memory, data obtained as a result of arithmetic operations in the ALU 1411, or the like.

The pipeline register 1410 has a function of temporarily storing data used for arithmetic operations of the ALU 1411, data obtained as a result of arithmetic operations of the ALU 1411, or the like.

The bus interface 1405 has a function as a path for data between the semiconductor device 1400 and various devices outside the semiconductor device 1400. The debug interface 1406 has a function as a path of a signal for inputting an instruction to control debugging to the semiconductor device 1400.

The power switch 1403 has a function of controlling supply of a power source voltage to various circuits included in the semiconductor device 1400 other than the power controller 1402. The above various circuits belong to several different power domains. The power switch 1403 controls whether the power supply voltage is supplied to the various circuits in the same power domain. In addition, the power controller 1402 has a function of controlling the operation of the power switch 1403.

The semiconductor device 1400 having the above structure is capable of performing power gating. A description will be given of an example of the power gating operation sequence.

First, by the CPU core 1401, timing for stopping the supply of the power supply voltage is set in a register of the power controller 1402. Then, an instruction of starting power gating is sent from the CPU core 1401 to the power controller 1402. Then, various registers and the cache 1404 included in the semiconductor device 1400 start data storing. Then, the power switch 1403 stops the supply of a power supply voltage to the various circuits other than the power controller 1402 included in the semiconductor device 1400. Then, an interrupt signal is input to the power controller 1402, whereby the supply of the power supply voltage to the various circuits included in the semiconductor device 1400 is started. Note that a counter may be provided in the power controller 1402 to be used to determine the timing of starting the supply of the power supply voltage regardless of input of an interrupt signal. Next, the various registers and the cache 1404 start data recovery. Then, the instruction is resumed in the control unit 1407.

Such power gating can be performed in the whole processor or one or a plurality of logic circuits forming the processor. Furthermore, power supply can be stopped even for a short time. Consequently, power consumption can be reduced finely in terms of a space or time.

In performing power gating, data held by the CPU core 1401 or the peripheral circuit 1422 is preferably restored in a short time. In that case, the power can be turned on or off in a short time, and an effect of saving power becomes significant.

In order that the data held by the CPU core 1401 or the peripheral circuit 1422 be restored in a short time, the data is preferably restored to a flip-flop circuit itself (referred to as a flip-flop circuit capable of backup operation). Furthermore, the data is preferably restored to an SRAM cell itself (referred to as an SRAM cell capable of backup operation). The flip-flop circuit and SRAM cell which are capable of backup operation preferably include transistors including an oxide semiconductor (preferably an oxide containing In, Ga, and Zn) in a channel formation region. Consequently, the transistor has a low off-state current; thus, the flip-flop circuit and SRAM cell which are capable of backup operation can retain data for a long time without power supply. When the transistor has a high switching speed, the flip-flop circuit and SRAM cell which are capable of backup operation can restore and return data in a short time in some cases.

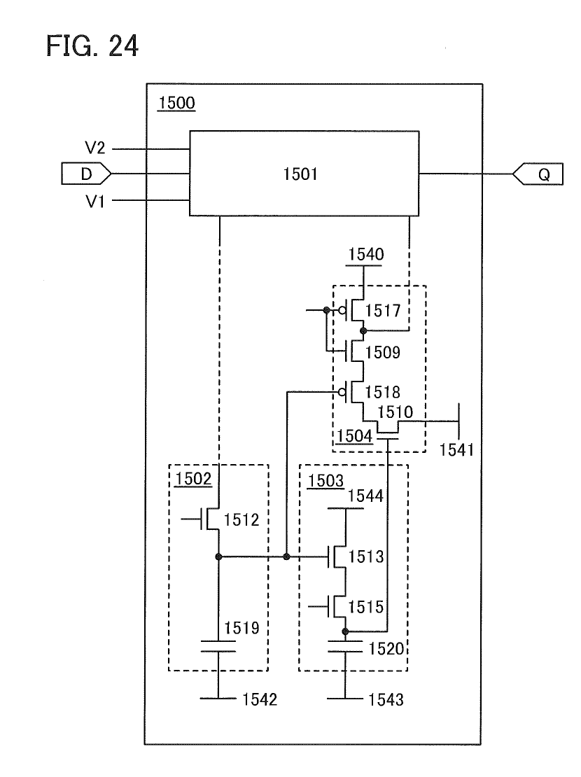

An example of the flip-flop circuit capable of backup operation is described using FIG. 24.

A semiconductor device 1500 shown in FIG. 24 is an example of the flip-flop circuit capable of backup operation. The semiconductor device 1500 includes a first memory circuit 1501, a second memory circuit 1502, a third memory circuit 1503, and a read circuit 1504. As a power supply voltage, a potential difference between a potential V1 and a potential V2 is supplied to the semiconductor device 1500. One of the potential V1 and the potential V2 is at a high level, and the other is at a low level. An example of the structure of the semiconductor device 1500 when the potential V1 is at a low level and the potential V2 is at a high level will be described below.

The first memory circuit 1501 has a function of retaining data when a signal D including the data is input in a period during which the power supply voltage is supplied to the semiconductor device 1500. Furthermore, the first memory circuit 1501 outputs a signal Q including the retained data in the period during which the power supply voltage is supplied to the semiconductor device 1500. On the other hand, the first memory circuit 1501 cannot retain data in a period during which the power supply voltage is not supplied to the semiconductor device 1500. That is, the first memory circuit 1501 can be referred to as a volatile memory circuit.

The second memory circuit 1502 has a function of reading the data held in the first memory circuit 1501 to store (or restore) it. The third memory circuit 1503 has a function of reading the data held in the second memory circuit 1502 to store (or restore) it. The read circuit 1504 has a function of reading the data held in the second memory circuit 1502 or the third memory circuit 1503 to store (or return) it in (to) the first memory circuit 1501.

In particular, the third memory circuit 1503 has a function of reading the data held in the second memory circuit 1502 to store (or restore) it even in the period during which the power supply voltage is not supplied to the semiconductor device 1500.

As shown in FIG. 24, the second memory circuit 1502 includes a transistor 1512 and a capacitor 1519. The third memory circuit 1503 includes a transistor 1513, a transistor 1515, and a capacitor 1520. The read circuit 1504 includes a transistor 1510, a transistor 1518, a transistor 1509, and a transistor 1517.

The transistor 1512 has a function of charging and discharging the capacitor 519 in accordance with data held in the first memory circuit 1501. The transistor 1512 is desirably capable of charging and discharging the capacitor 1519 at a high speed in accordance with data held in the first memory circuit 1501. Specifically, the transistor 1512 desirably contains crystalline silicon (preferably polycrystalline silicon, further preferably single crystal silicon) in a channel formation region.

The conduction state or the non-conduction state of the transistor 1513 is determined in accordance with the charge held in the capacitor 1519. The transistor 1515 has a function of charging and discharging the capacitor 1520 in accordance with the potential of a wiring 1544 when the transistor 1513 is in a conduction state. It is desirable that the off-state current of the transistor 1515 be extremely low. Specifically, the transistor 1515 desirably contains an oxide semiconductor (preferably an oxide containing In, Ga, and Zn) in a channel formation region.

Specific connection relations between the elements are described. One of a source and a drain of the transistor 1512 is connected to the first memory circuit 1501. The other of the source and the drain of the transistor 1512 is connected to one electrode of the capacitor 1519, a gate of the transistor 1513, and a gate of the transistor 1518. The other electrode of the capacitor 1519 is connected to the wiring 1542. One of a source and a drain of the transistor 1513 is connected to the wiring 1544. The other of the source and the drain of the transistor 1513 is connected to one of a source and a drain of the transistor 1515. The other of the source and the drain of the transistor 1515 is connected to one electrode of the capacitor 1520 and a gate electrode of the transistor 1510. The other electrode of the capacitor 1520 is connected to the wiring 1543. One of a source and a drain of the transistor 1510 is connected to a wiring 1541. The other of the source and the drain of the transistor 1510 is connected to one of a source and a drain of the transistor 1518. The other of the source and the drain of the transistor 1518 is connected to one of a source electrode and a drain electrode of the transistor 1509. The other of the source and the drain of the transistor 1509 is connected to one of a source and a drain of the transistor 1517 and the first memory circuit 1501. The other of the source and the drain of the transistor 1517 is connected to a wiring 1540. Furthermore, although a gate of the transistor 1509 is connected to a gate of the transistor 1517 in FIG. 24, the gate of the transistor 1509 is not necessarily connected to the gate of the transistor 1517.

The transistor described in the above embodiment as an example can be applied to the transistor 1515. Because of the low off-state current of the transistor 1515, the semiconductor device 1500 can retain data for a long time without power supply. The favorable switching characteristics of the transistor 1515 allow the semiconductor device 1500 to perform high-speed backup and recovery.

At least part of this embodiment can be implemented in combination with any of the other embodiments and the other examples described in this specification as appropriate.

### Embodiment 6

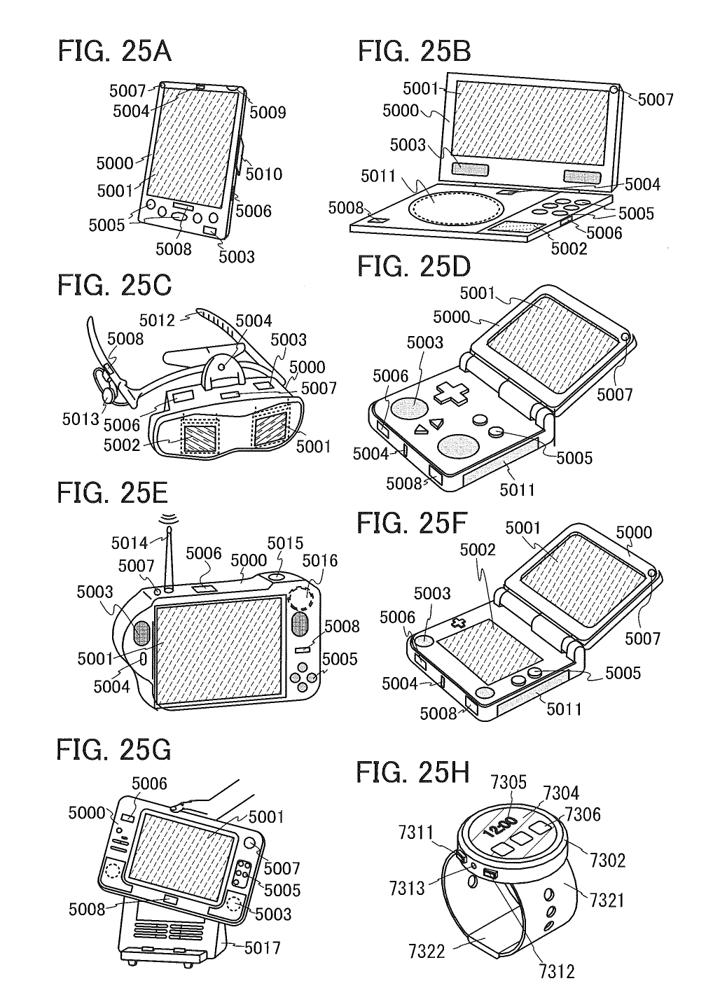

In this embodiment, electronic devices each of which includes the information processing device of one embodiment of the present invention will be described with reference to FIGS. 25A to 25H.

FIGS. 25A to 25G illustrate electronic devices. These electronic devices can include a housing 5000, a display portion 5001, a speaker 5003, an LED lamp 5004, operation keys 5005 (including a power switch and an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 25A illustrates a mobile computer that can include a switch 5009, an infrared port 5010, and the like in addition to the above components. FIG. 25B illustrates a portable image reproducing device (e.g., a DVD reproducing device) provided with a recording medium, and the portable image reproducing device can include a second display portion 5002, a recording medium reading portion 5011, and the like in addition to the above components. FIG. 25C illustrates a goggle-type display that can include the second display portion 5002, a support portion 5012, an earphone 5013, and the like in addition to the above components. FIG. 25D illustrates a portable game console that can include the recording medium reading portion 5011 and the like in addition to the above components. FIG. 25E illustrates a digital camera with a television reception function, and the digital camera can include an antenna 5014, a shutter button 5015, an image receiving portion 5016, and the like in addition to the above components. FIG. 25F illustrates a portable game console that can include the second display portion 5002, the recording medium reading portion 5011, and the like in addition to the above components. FIG. 25G illustrates a portable television receiver that can include a charger 5017 capable of transmitting and receiving signals, and the like in addition to the above components.

The electronic devices in FIGS. 25A to 25G can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion. Furthermore, the electronic device including a plurality of display portions can have a function of displaying image data mainly on one display portion while displaying text data mainly on another display portion, a function of displaying a three-dimensional image by displaying images on a plurality of display portions with a parallax taken into account, or the like. Furthermore, the electronic device including an image receiving portion can have a function of shooting a still image, a function of taking moving images, a function of automatically or manually correcting a shot image, a function of storing a shot image in a recording medium (an external recording medium or a recording medium incorporated in the camera), a function of displaying a shot image on the display portion, or the like. Note that functions of the electronic devices in FIGS. 25A to 25G are not limited thereto, and the electronic devices can have a variety of functions.

FIG. 25H illustrates a smart watch, which includes a housing 7302, a display panel 7304, operation buttons 7311 and 7312, a connection terminal 7313, a band 7321, a clasp 7322, and the like.

The display panel 7304 mounted in the housing 7302 serving as a bezel includes a non-rectangular display region. The display panel 7304 may have a rectangular display region. The display panel 7304 can display an icon 7305 indicating time, another icon 7306, and the like.

The smart watch in FIG. 25H can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

The housing 7302 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. Note that the smart watch can be manufactured using the light-emitting element for the display panel 7304.

This embodiment can be combined with any of the other embodiments in this specification as appropriate.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is conducting or not conducting (is turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, and a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to X at least with a first connection path through Z1, the first connection path does not include a second connection path, the second connection path includes a connection path through which the transistor is provided, a drain (or a second terminal or the like) of the transistor is electrically connected to Y at least with a third connection path through Z2, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

This application is based on Japanese Patent Application serial no. 2016-024221 filed with Japan Patent Office on Feb. 11, 2016, the entire contents of which are hereby incorporated by reference.

What is claimed is:

1. An information processing device comprising:
a housing;
an attitude sensor;
a plurality of photosensors; and
an arithmetic device,
wherein the attitude sensor is configured to sense an attitude of the housing,
wherein the attitude sensor is configured to supply attitude information based on the attitude,
wherein the housing includes a plurality of regions,
wherein the plurality of photosensors are configured to measure illuminance in each of the plurality of regions,
wherein the plurality of photosensors are configured to supply illuminance information based on the illuminance,
wherein the arithmetic device is configured to select at least one region from the plurality of regions on the basis of the attitude information, and
wherein the arithmetic device is configured to operate on the basis of the illuminance information of the selected region.

2. The information processing device according to claim 1,
wherein the arithmetic device is configured to select a region on the top among the plurality of regions.

3. The information processing device according to claim 1, further comprising:
a sensor portion,
wherein the sensor portion is configured to drive a photosensor of the selected region.

4. The information processing device according to claim 1, further comprising:
a display portion,
wherein the housing is configured to house the display portion,
wherein the display portion includes a selection circuit and a display panel,
wherein the display panel is electrically connected to the selection circuit,
wherein the selection circuit is configured to receive control information, image information, or background information,
wherein the selection circuit is configured to supply the image information or the background information based on the control information,
wherein the display panel includes a signal line and a pixel,
wherein the signal line is configured to receive an image signal based on the image information or the background information,
wherein the pixel is electrically connected to the signal line,
wherein the pixel includes a pixel circuit, a first display element, and a second display element,
wherein the first display element is electrically connected to the pixel circuit, and
wherein the second display element is electrically connected to the pixel circuit.

5. The information processing device according to claim 4, further comprising:
a group of a plurality of pixels;
another group of a plurality of pixels; and
a scan line,
wherein the pixel is included in the group of the plurality of pixels,
wherein the group of the plurality of pixels are arranged in a row direction,
wherein the pixel is included in the another group of the plurality of pixels,
wherein the another group of the plurality of pixels are arranged in a column direction intersecting the row direction,
wherein the scan line is electrically connected to the group of the plurality of pixels, and
wherein the another group of the plurality of pixels are electrically connected to the signal line.

6. The information processing device according to claim 4,
wherein the pixel includes a second conductive film, a first conductive film, and a first insulating film,
wherein the second conductive film is electrically connected to the pixel circuit,
wherein the first conductive film includes a region overlapping with the second conductive film,
wherein the first insulating film includes a region between the second conductive film and the first conductive film,
wherein the first insulating film includes an opening in the region between the first conductive film and the second conductive film,
wherein the first conductive film is electrically connected to the second conductive film in the opening,
wherein the first display element is electrically connected to the first conductive film,
wherein the first display element is configured to control an intensity of light reflected by a reflective film,
wherein the second display element is configured to emit light toward the first insulating film, and
wherein the reflective film has a shape including a region that does not block light emitted from the second display element.

7. The information processing device according to claim 6,
wherein the reflective film includes one or a plurality of openings, and
wherein the second display element is configured to emit light toward the opening.

8. The information processing device according to claim 4,
wherein the second display element is provided so that display using the second display element can be seen from part of a region from that display using the first display element can be seen.

9. The information processing device according to claim 4, further comprising:
an input portion,
wherein the input portion includes a region overlapping with the display panel,
wherein the input portion includes a control line, a sensor signal line, and a sensing element,
wherein the sensing element is electrically connected to the control line and the sensor signal line,
wherein the control line is configured to supply a control signal,
wherein the sensing element receives the control signal,
wherein the sensing element is configured to supply the control signal and a sensor signal that changes in accordance with a distance between the sensing element and an object approaching the region overlapping with the display panel,
wherein the sensor signal line is configured to receive the sensor signal,
wherein the sensing element has a light-transmitting property,
wherein the sensing element includes a first electrode and a second electrode,
wherein the first electrode is electrically connected to the control line,
wherein the second electrode is electrically connected to the sensor signal line, and
wherein the second electrode is provided so that an electric field that is partly blocked by the object approaching the region overlapping with the display panel is generated between the first electrode and the second electrode.

10. The information processing device according to claim 1, further comprising at least one of a keyboard, a hardware button, a pointing device, a touch sensor, an imaging device, an audio input device, and a viewpoint input device.
